(19) United States
(12) Patent Application Publication
(10) Pub. No.: US 2018/0307451 A1
(43) Pub. Date: Oct. 25, 2018

(54) ELECTRONIC DEVICE

(71) Applicant: Semiconductor Energy Laboratory Co., Ltd., Atsugi-shi, Kanagawa-ken (JP)

(72) Inventors: Shunpei YAMAZAKI, Setagaya, Tokyo (JP); Hajime KIMURA, Atsugi, Kanagawa (JP)

(21) Appl. No.: 15/569,539

(22) PCT Filed: Apr. 18, 2016
(86) PCT No.: PCT/IB2016/052189

§ 371 Date: Oct. 26, 2017

(30) Foreign Application Priority Data
Apr. 30, 2015 (JP) 2015-093291

(51) Int. Cl. G06F 3/14; H01L 27/12; H04N 21/436; H04N 7/18

(52) U.S. Cl. CPC G06F 3/14; H04N 7/18; H04N 21/436; H01L 27/1225

(57) ABSTRACT

An electronic device which can transmit an image signal stably at high speed.

It is a semiconductor device which includes a signal output device and a display device and which has a structure where the signal output device has a function of dividing an image signal into a plurality of image signals, the display device has a function of combining the divided image signals, and a wired transmission path and a wireless transmission path through which the divided image signals are transmitted are provided between the signal output device and the image display device.

### TECHNICAL FIELD

One embodiment of the present invention relates to an electronic device which conducts input, output, or input/output of data.

Note that one embodiment of the present invention is not limited to the above technical field. The technical field of one embodiment of the invention disclosed in this specification and the like relates to an object, a method, or a manufacturing method. Furthermore, one embodiment of the present invention relates to a process, a machine, manufacture, or a composition of matter. Specifically, examples of the technical field of one embodiment of the present invention disclosed in this specification include a semiconductor device, a display device, a liquid crystal display device, a light-emitting device, a lighting device, a power storage device, a storage device, an imaging device, a method for driving any of them, and a method for manufacturing any of them.

In this specification and the like, a semiconductor device generally means a device that can function by utilizing semiconductor characteristics. A transistor and a semiconductor circuit are embodiments of semiconductor devices. In some cases, a storage device, a display device, an imaging device, or an electronic device includes a semiconductor device.

### PRIOR ART

Communication technology and data processing technology have been developed to enable even a small-sized portable information terminal to display a high-definition image at high speed. A wired transmission system and a wireless transmission system are known as technologies for transmitting data signals and are each being developed for next-generation high-speed data transmission for large contents.

In contrast, wireless transmission sometimes cannot provide a sufficient transmission speed because of, for example, a distance, an obstruction, and interference by another device which uses radio waves with the same frequency bands. As a solution for these problems, for example, Patent Document 1 discloses a communication system which uses a combination of a wireless transmission path and a power line transmission path.

### REFERENCES

### Patent Document

### [Patent Document 1] Japanese Published Patent Application No. 2008-193305

### SUMMARY OF THE INVENTION

### Problem to be Solved the Invention

A high-definition image standard such as 8K4K requires even a large amount of image data, and delay of image display might be generated in an environment with unstable communication speed. In the next generation, an increase in the amount of data is advanced, and higher speed and more stable transmission technology is desired.

In view of the above, an object of one embodiment of the present invention is to provide an electronic device which can transmit image signals stably at high speed. Another object is to provide an electronic device which includes a plurality of transmission paths for image signals. Another object is to provide an electronic device which includes a plurality of transmission paths for image signals and selects an appropriate transmission path. Another object is to provide an electronic device which outputs image signals to a plurality of transmission paths. Another object is to provide an electronic device which obtains image signals from a plurality of transmission paths. Another object is to provide an electronic device which outputs image signals to a plurality of transmission paths and obtains image signals from the plurality of transmission paths. Another object is to provide an electronic device which includes a novel display device. Another object is to provide a novel electronic device or the like.

Note that the descriptions of these objects do not disturb the existence of other objects. In one embodiment of the present invention, there is no need to achieve all the objects. Other objects will be apparent from and can be derived from the description of the specification, the drawings, the claims, and the like.

### Means for Solving the Problem

One embodiment of the present invention relates to an electronic device including a plurality of transmission paths for image signals.

One embodiment of the present invention is an electronic device including a signal output device and a display device, characterized in that the signal output device has a function of dividing an image signal into a plurality of signals, the display device has a function of combining the plurality of signals, the plurality of signals includes a first signal and a second signal, the signal output device has a function of transmitting the first signal to the display device via a wired transmission path, and the signal output device has a function of transmitting the second signal to the display device via a wireless transmission path.

Another embodiment of the present invention is an electronic device including a signal output device and a display device, characterized in that the signal output device has a function of transmitting a first signal to the display device via a wired transmission path, the signal output device has a function of transmitting a second signal to the display device via a wireless transmission path, the signal output device includes a first circuit, a second circuit, a third circuit, a fourth circuit, and a first antenna, the first circuit has a function of selecting a transmission path of an image signal, the second circuit has a function of dividing an image signal transmitted from the first circuit into a plurality of signals, the plurality of signals includes the first signal and the second signal, the third circuit has a function of converting the first signal transmitted from the second circuit into a modulation signal, the fourth circuit has a function of sending the modulation signal transmitted from the third circuit with use of the first antenna, the display device includes a fifth circuit, a sixth circuit, a seventh circuit, a second antenna, and a display portion, the fifth circuit has a function of receiving the modulation signal sent from the fourth circuit with use of the second antenna, the sixth circuit has a function of demodulating the modulation signal transmitted from the fifth circuit and converting it to the first signal, and the seventh circuit has a function of composing an image displayed on the display portion from the second signal transmitted from the second circuit and the first signal transmitted from the sixth circuit.

The fourth circuit can have a function of sending the modulation signal with use of electric waves with a plurality of frequency bands.

The fifth circuit can have a function of receiving the modulation signal sent with use of electric waves with a plurality of frequency bands.

The number of wired transmission paths is two or more.

The signal output device and the display device can include a transistor in which an oxide semiconductor is included in an active layer. The oxide semiconductor preferably includes In, Zn, and M (M is Al, Ti, Ga, Sn, Y, Zr, La, Ce, Nd, or Hf).

### Effect of the Invention

By using one embodiment of the present invention, an electronic device which can transmit image signals stably at high speed can be provided. Furthermore, an electronic device which includes a plurality of transmission paths for image signals can be provided. Furthermore, an electronic device which includes a plurality of transmission paths for image signals and selects an appropriate transmission path can be provided. Furthermore, an electronic device which outputs image signals to a plurality of transmission paths can be provided. Furthermore, an electronic device which obtains image signals from a plurality of transmission paths can be provided. Furthermore, an electronic device which outputs image signals to a plurality of transmission paths and obtains image signals from the plurality of transmission paths can be provided. Furthermore, an novel electronic device which includes a display device can be provided. Furthermore, a novel electronic device or the like can be provided.

Note that one embodiment of the present invention is not limited to these effects. For example, depending on circumstances or conditions, one embodiment of the present invention might produce another effect. Furthermore, depending on circumstances or conditions, one embodiment of the present invention might not produce any of the above effects.

### BRIEF DESCRIPTION OF THE DRAWINGS

FIG. 1 A block diagram illustrating an electronic apparatus.

FIG. 2 A block diagram illustrating an electronic apparatus.

FIG. 3 A flow chart showing the operation of an electronic device.

FIG. 4 A flow chart showing the operation of an electronic device.

FIG. 5 A block diagram illustrating an electronic apparatus.

FIG. 6 Block diagrams illustrating electronic apparatuses.

FIG. 7 Diagrams illustrating a connection mode of a signal output device and a display device.

FIG. 8 A top view and a cross-sectional view illustrating a transistor.

FIG. 9 Cross-sectional views illustrating transistors.

FIG. 10 A top view and a cross-sectional view illustrating a transistor.

FIG. 11 A top view and a cross-sectional view illustrating a transistor.

FIG. 12 Cross-sectional views illustrating circuits included in semiconductor devices.

FIG. 13 Circuit diagrams illustrating circuits included in semiconductor devices.

FIG. 14 A cross-sectional view illustrating a circuit included in a semiconductor device.

FIG. 15 Cross-sectional views illustrating circuits included in semiconductor devices.

FIG. 16 A cross-sectional view and circuit diagrams illustrating circuits included in semiconductor devices.

FIG. 17 A circuit diagram, a top view, and a cross-sectional view illustrating a display device.

FIG. 18 A circuit diagram and a cross-sectional view illustrating a display device.

FIG. 19 Diagrams illustrating electronic devices.

### EMBODIMENTS FOR IMPLEMENTING THE INVENTION

Embodiments will be described in detail with reference to the drawings. Note that the present invention is not limited to the following description and it will be readily appreciated by those skilled in the art that modes and details can be modified in various ways without departing from the spirit and the scope of the present invention. Therefore, the present invention should not be interpreted as being limited to the description of embodiments below. Note that in structures of the present invention described below, the same portions or portions having similar functions are denoted by the same reference numerals in different drawings, and description thereof is not repeated in some cases. It is also to be noted that the same components are denoted by different hatching patterns in different drawings, or the hatching patterns are omitted in some cases.

For example, in this specification and the like, an explicit description “X and Y are connected” means that X and Y are electrically connected, X and Y are functionally connected, and X and Y are directly connected. Accordingly, without being limited to a predetermined connection relationship, for example, a connection relationship shown in drawings or texts, another connection relationship is included in the drawings or the texts.

Here, X and Y each denote an object (e.g., a device, an element, a circuit, a wiring, an electrode, a terminal, a conductive film, or a layer).

Examples of the case where X and Y are directly connected include the case where an element that allows an electrical connection between X and Y (e.g., a switch, a transistor, a capacitor, an inductor, a resistor, a diode, a display element, a light-emitting element, or a load) is not connected between X and Y, and the case where X and Y are connected without the element that allows the electrical connection between X and Y provided therebetween.

For example, in the case where X and Y are electrically connected, one or more elements that allow an electrical connection between X and Y (e.g., a switch, a transistor, a capacitor, an inductor, a resistor, a diode, a display element, a light-emitting element, or a load) can be connected between X and Y. Note that the switch is controlled to be turned on or off. That is, the switch is turned on or off to determine whether current flows therethrough or not. Alternatively, the switch has a function of selecting and changing a current path. Note that the case where X and Y are electrically connected includes the case where X and Y are directly connected.

For example, in the case where X and Y are functionally connected, one or more circuits that allow a functional connection between X and Y (e.g., a logic circuit such as an inverter, a NAND circuit, or a NOR circuit; a signal converter circuit such as a D/A converter circuit, an A/D converter circuit, or a gamma correction circuit; a potential level converter circuit such as a power supply circuit (e.g., a step-up circuit or a step-down circuit) or a level shifter circuit for changing the potential level of a signal; a voltage source; a current source; a switching circuit; an amplifier circuit such as a circuit that can increase signal amplitude, the amount of current, or the like, an operational amplifier, a differential amplifier circuit, a source follower circuit, or a buffer circuit; a signal generation circuit; a memory circuit; or a control circuit) can be connected between X and Y. For example, even when another circuit is interposed between X and Y, X and Y are functionally connected if a signal output from X is transmitted to Y. Note that the case where X and Y are functionally connected includes the case where X and Y are directly connected and the case where X and Y are electrically connected.

Note that in this specification and the like, an explicit description “X and Y are electrically connected” means that X and Y are electrically connected (i.e., the case where X and Y are connected with another element or another circuit provided therebetween), X and Y are functionally connected (i.e., the case where X and Y are functionally connected with another circuit provided therebetween), and X and Y are directly connected (i.e., the case where X and Y are connected without another element or another circuit provided therebetween). That is, in this specification and the like, the explicit description “X and Y are electrically connected” is the same as the description “X and Y are connected.”

For example, any of the following expressions can be used for the case where a source (or a first terminal or the like) of a transistor is electrically connected to X through (or not through) Z1 and a drain (or a second terminal or the like) of the transistor is electrically connected to Y through (or not through) Z2, or the case where a source (or a first terminal or the like) of a transistor is directly connected to one part of Z1 and another part of Z1 is directly connected to X while a drain (or a second terminal or the like) of the transistor is directly connected to one part of Z2 and another part of Z2 is directly connected to Y.

Examples of the expressions include, “X, Y, a source (or a first terminal or the like) of a transistor, and a drain (or a second terminal or the like) of the transistor are electrically connected to each other, and X, the source (or the first terminal or the like) of the transistor, the drain (or the second terminal or the like) of the transistor, and Y are electrically connected to each other in this order,” “a source (or a first terminal or the like) of a transistor is electrically connected to X, a drain (or a second terminal or the like) of the transistor is electrically connected to Y, and X, the source (or the first terminal or the like) of the transistor, the drain (or the second terminal or the like) of the transistor, and Y are electrically connected to each other in this order,” and “X is electrically connected to Y through a source (or a first terminal or the like) and a drain (or a second terminal or the like) of a transistor, and X, the source (or the first terminal or the like) of the transistor, the drain (or the second terminal or the like) of the transistor, and Y are provided to be connected in this order.” When the connection order in a circuit configuration is defined by an expression similar to the above examples, a source (or a first terminal or the like) and a drain (or a second terminal or the like) of a transistor can be distinguished from each other to specify the technical scope.

Other examples of the expressions include, “a source (or a first terminal or the like) of a transistor is electrically connected to X through at least a first connection path, the first connection path does not include a second connection path, the second connection path is a path between the source (or the first terminal or the like) of the transistor and a drain (or a second terminal or the like) of the transistor, Z1 is on the first connection path, the drain (or the second terminal or the like) of the transistor is electrically connected to Y through at least a third connection path, the third connection path does not include the second connection path, and Z2 is on the third connection path” and “a source (or a first terminal or the like) of a transistor is electrically connected to X at least with a first connection path through Z1, the first connection path does not include a second connection path, the second connection path includes a connection path through which the transistor is provided, a drain (or a second terminal or the like) of the transistor is electrically connected to Y at least with a third connection path through Z2, and the third connection path does not include the second connection path.” Still another example of the expression is “a source (or a first terminal or the like) of a transistor is electrically connected to X through at least Z1 on a first electrical path, the first electrical path does not include a second electrical path, the second electrical path is an electrical path from the source (or the first terminal or the like) of the transistor to a drain (or a second terminal or the like) of the transistor, the drain (or the second terminal or the like) of the transistor is electrically connected to Y through at least 22 on a third electrical path, the third electrical path does not include a fourth electrical path, and the fourth electrical path is an electrical path from the drain (or the second terminal or the like) of the transistor to the source (or the first terminal or the like) of the transistor.” When the connection path in a circuit structure is defined by an expression similar to the above examples, a source (or a first terminal or the like) and a drain (or a second terminal or the like) of a transistor can be distinguished from each other to specify the technical scope.

Note that these expressions are examples and there is no limitation on the expressions. Here, X, Y, Z1, and Z2 each denote an object (e.g., a device, an element, a circuit, a wiring, an electrode, a terminal, a conductive film, or a layer).

Even when independent components are electrically connected to each other in a circuit diagram, one component has functions of a plurality of components in some cases. For example, when part of a wiring also functions as an electrode, one conductive film functions as the wiring and the electrode. Thus, “electrical connection” in this specification includes in its category such a case where one conductive film has functions of a plurality of components.

Note that the terms “film” and “layer” can be interchanged with each other depending on the case or circumstances. For example, the term “conductive layer” can be changed into the term “conductive film” in some cases. Also, the term “insulating film” can be changed into the term “insulating layer” in some cases.

### Embodiment 1

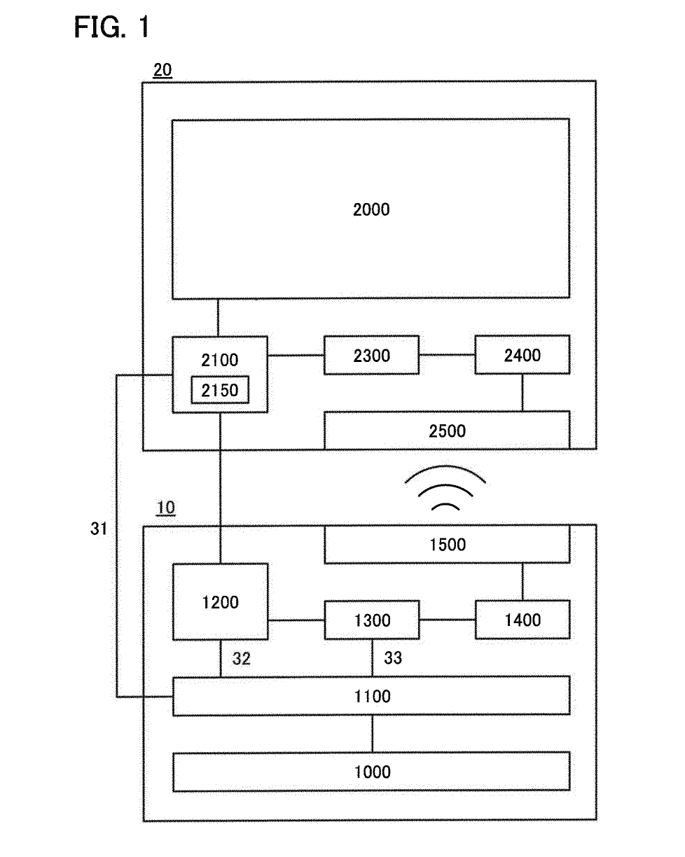

In this embodiment, an electronic device that is one embodiment of the present invention is described with reference to drawings. FIG. 1 is a block diagram illustrating an electronic device of one embodiment of the present invention. The electronic device includes a signal output device 10 and a display device 20.

The signal output device 10 includes a signal reading device 1000, a circuit 1100, a circuit 1200, a circuit 1300, a circuit 1400, and an antenna 1500. The display device 20 includes a display portion 2000, a circuit 2100, a circuit 2300, a circuit 2400, and an antenna 2500. Note that the structure is an example, and a circuit which controls the above-described elements may be provided. In addition, a storage circuit temporarily storing data which is to be processed by the above elements may be provided. Alternatively, a structure in which some of the elements are not provided, a structure in which an element other than the above is provided, or a structure in which some of the elements are integrated may be employed.

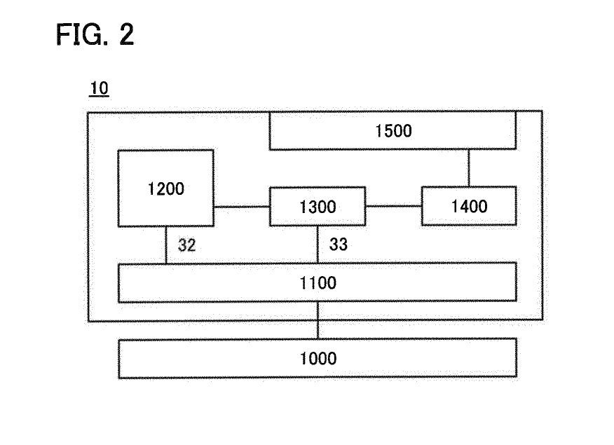

The signal reading device 1000 has a function of reading an image signal. For example, it can have a function of reading an image signal from a recording medium. Alternatively, it can have a function of receiving an electric wave output from a broadcasting station or the like and converting it to an image signal. Further alternatively, it can have a function of taking out an image signal delivered from a network such as the Internet. Further alternatively, it has an image capturing function and can have a function of taking out an image signal. In other words, the signal output device 10 including the signal reading device 1000 can have a form of a reproducing device of a recording medium, a tuner, a portable information terminal, a computer, a camera, or the like. Note that as illustrated in FIG. 2, a structure in which the signal reading device 1000 is not included in the signal output device 10 may be employed.

The circuit 1100 has a function of selecting a path for transmitting an image signal which is transmitted from the signal reading device 1000 to the outside of the signal output device 10 efficiently at high speed. There are a wired transmission path and a wireless transmission path as the transmission path for outputting an image signal from the signal output device 10 to the outside, and the transmission path is determined depending on the image signal and an environment.

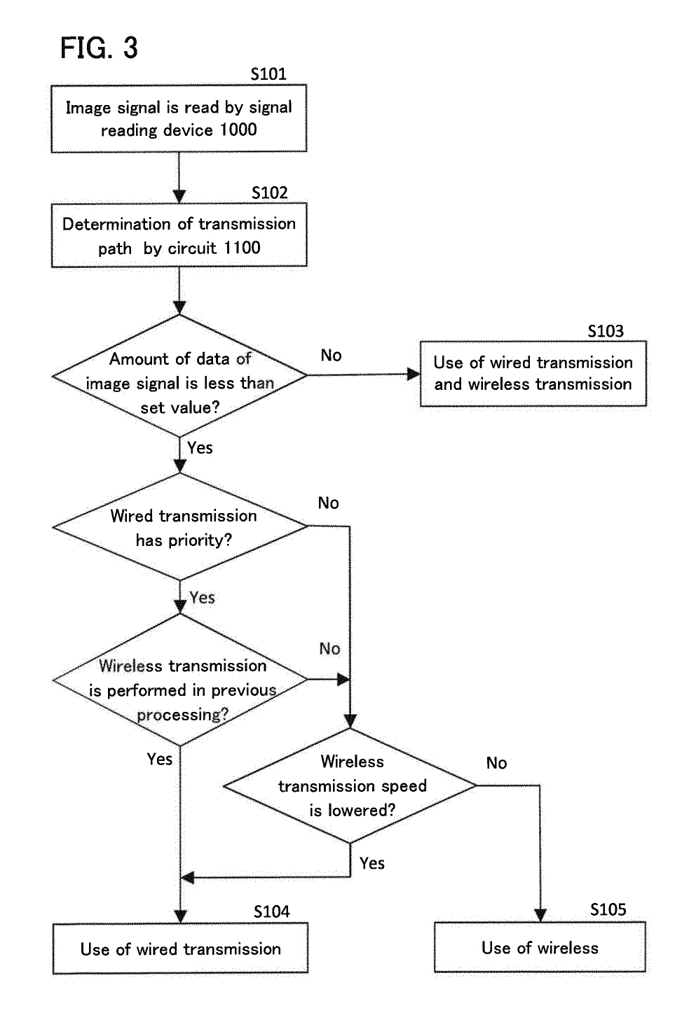

An example of determination by the circuit 1100 is shown in a flow chart of FIG. 3. First, an image signal is read by the confidence reading device 1000 (S101). Next, determination of a transmission path of the image signal is made by the circuit 1100 (S102). A single-color image, a binary image, and the like with a small amount of data can be transmitted at high speed through one of the wired transmission path and the wireless transmission path. Therefore, a threshold value for determining the size of data of the image signal is set in advance, and in the case where the amount of the data is determined to be small, it is determined that transmission is performed with one of the wired transmission path and the wireless transmission path.

Whether the wired transmission path or the wireless transmission path is used is comprehensively determined by, for example, a configuration in which wired transmission has priority, a configuration in which wired transmission and wireless transmission are alternately performed, a configuration in which wired transmission has priority when a wireless transmission speed is lowered, or the like. When wired transmission is determined to be used (S104), the image signal can be transmitted directly to the display device 20 with the use of a wired transmission path 31. When wireless transmission is determined to be used (S105), the image signal can be transmitted to the display device 20 by wireless transmission through a path 33. Note that it is also possible to transmit different image signals by wired transmission and wireless transmission concurrently.

Since an image of 8K4K, 16K8K, or more has an extremely large amount of data, the circuit 1100 makes a determination that the image signal is transmitted to the display device 20 with the use of both wired transmission and wireless transmission (S103). In that case, the image signal is transmitted from the circuit 1100 to the circuit 1200 through a path 32.

The circuit 1200 has a function of dividing the transmitted image signal into a plurality of pieces. Here, an example in which one image signal is divided into two is described. Note that as division of an image signal, an example of division of an image into a right part and a left part, an example of division of an image into an upper part and a lower part, an example of division into an image corresponding to odd-numbered rows of pixels and an image corresponding to even-numbered rows, and the like are given. Note that the proportions of the amounts of data of signals which have been separated is not necessarily equal but may be different from each other. In that case, for example, wired transmission that has a high transmission speed is used for a divided signal with a large amount of data and wireless transmission that has a low transmission speed is used for a divided signal with a small amount of data, whereby the whole transmission speed can be adjusted. Note that the circuit 1200 may have a function of an encoder which compresses an image signal.

Note that in the case of division of the image into the upper part and the lower part, a source signal line may be cut at the center of a screen in the display portion 2000, and signals may be input to the upper part of the screen and the lower part of the screen concurrently. In other words, screen division may be performed and signals may be input. Accordingly, one gate selection period can be long, so that display can be displayed easily.

In addition, part of the image signal can be extracted and a transmission path can be assigned thereto. For example, a luminance signal and a color signal can be transmitted through different transmission paths.

Furthermore, in the case of a moving image or the like, the image signal can be divided by time axis. For example, an odd-numbered frame and an even-numbered frame can be transmitted through different transmission paths. In addition, the ratio of the number of frames to be transmitted may be divided into 2:1, 3:1, or the like, and one with a large proportion may be wired transmitted and the other with a small proportion may be wireless transmitted. A frame with a large amount of data may be transmitted by wire and a frame with a small amount of data may be wirelessly transmitted.

Wired transmission may be used in the case of displaying a moving image, and wireless transmission may be used in the case of displaying a still image. In particular, in the case where an oxide semiconductor is used for a transistor included in a pixel of a display device, the off-state current of the transistor can be reduced. Therefore, in the case of displaying a still image or in the case of displaying the same image for several frame periods, a speed at which data of a pixel is rewritten, i.e., a frame frequency can be reduced. In such a case, wireless transmission may be used.

Note that although an example of dividing the image signal is described above, an audio signal may be a subject of division. For example, an image signal can be transmitted by wire, and an audio signal can be wirelessly transmitted. In addition, an audio signal can be divided by frequency, and the individual divided signals can be transmitted through different transmission paths. Alternatively, an audio signal can be divided by time axis, and the individual divided signals can be transmitted through different transmission paths.

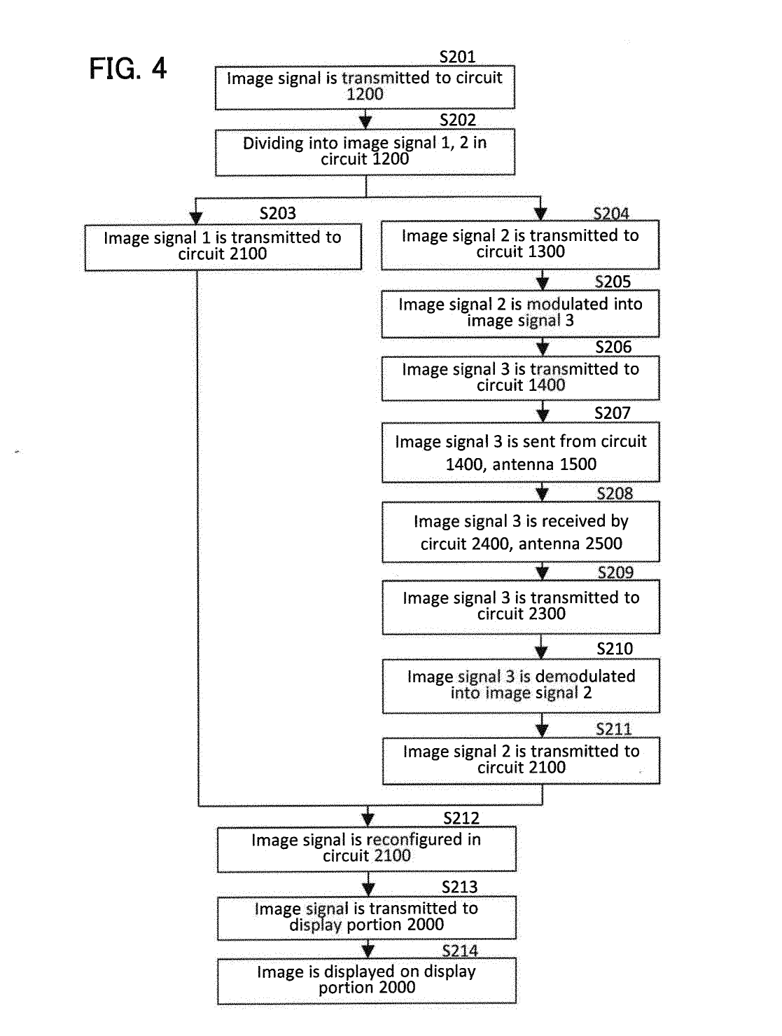

Examples of transmission paths of divided image signals and a processing method are described with reference to FIG. 4. First, an image signal is transmitted to the circuit 1200 (S201). Next, the image signal is divided in the circuit 1200 (S202). Here, the divided image signals are referred to as an image signal 1 and an image signal 2.

Next, the image signal 1 is transmitted to the circuit 2100 (S203). The image signal 2 is transmitted to the circuit 1300 (S204). The circuit 1300 has a function of modulating an image signal so that wireless transmission is performed. Note that a signal transmitted from the circuit 1100 directly to the circuit 1300 can also be modulated.

In the circuit 1300, the image signal 2 is modulated (S205). Here, the modulation signal is referred to as an image signal 3. Next, the image signal 3 is transmitted to the circuit 1400 (S206). The circuit 1400 has a function of sending the image signal 3 to the outside with the use of the antenna 1500.

The image signal 3 sent from the circuit 1400 (S207) is received by the circuit 2400 via the antenna 2500 (S208). The circuit 2400 has a function of receiving a modulation signal with the use of the antenna 2500.

The image signal 3 received by the circuit 2400 is transmitted to the circuit 2300 (S209). The circuit 2300 has a function of demodulating a modulation signal.

The image signal 2 demodulated by the circuit 2300 (S210) is transmitted to the circuit 2100 (S211). Next, the image signal 1 and the image signal 2 which have been separated by the circuit 1200 are combined by the circuit 2300 to be reconfigured to the original image signal (S212). Note that the circuit 2100 may have a function of a decoder which decompresses a compressed image signal.

Then, the image signal is transmitted to the display portion 2000 (S213) and an image based on the image signal is displayed (S214). Note that a wired transmission path is provided between the circuit 1200 and the circuit 2100.

Note that in the above-described transmission path from the circuit 1200 to the circuit 2100, the wireless transmission path requires time not only for sending and receiving wireless signals but also for modulation and demodulation of signals. Therefore, in general, the signal transmission speed of the wireless transmission path is lower than that of the wired transmission path. Therefore, it is effective that a temporary memory circuit 2150 of divided signals transmitted through the wired transmission path is provided in the circuit 2100. Note that the memory circuit 2150 may be provided as an element different from the circuit 2100. In addition, a memory circuit which has a similar function may be provided in the circuit 1200.

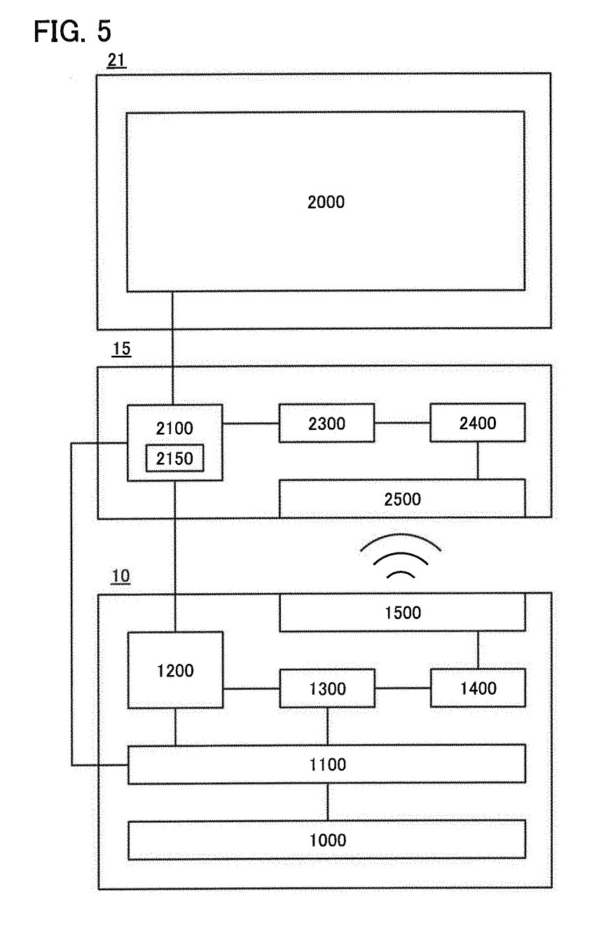

Although the configuration of the display device 20 which includes the circuit 2100, the circuit 2300, the circuit 2400, and the antenna 2500 is described above, a configuration which is divided into a display device 21 and a signal input/output device 15 as illustrated in FIG. 5 may be employed. The signal input/output device 15 includes the circuit 2100, the circuit 2300, the circuit 2400, the antenna 2500, and an output path of an image signal. With such a configuration, a display device which includes a display portion and has high versatility can be used as the display device 21. For example, the display device 20 and the display device 21 can have a form of a tablet computer, a television, a display for a computer, a timepiece with a display, or the like.

An electronic device including the signal output device 10 and the display device 20 illustrated in FIG. 1 can be installed in one housing. In addition, an electronic device included in the signal output device 10, the signal input/output device 15, and the display device 21 illustrated in FIG. 5 can be installed in one housing. In other words, the electronic device of one embodiment of the present invention can have a form of a television, digital signage, a computer including a display, a camera including a display, or the like.

The configuration in which an image signal is divided into two by the circuit 1200 in the above-described example; however, the image signal may be divided into three or more. In that case, although a method of transmitting divided signals sequentially may be used, the signal transmission time between the signal output device 10 and the display device 20 can be shortened in such a manner that divided signals are transmitted through a plurality of wired transmission paths and a plurality of wireless transmission paths in parallel. In that case, the combination of paths for transmitting divided signals in parallel is not limited to a combination of a wired transmission path and a wireless transmission path, and a combination of a plurality of wired transmission paths may be employed. Alternatively, a combination of a plurality of wireless transmission paths may be employed.

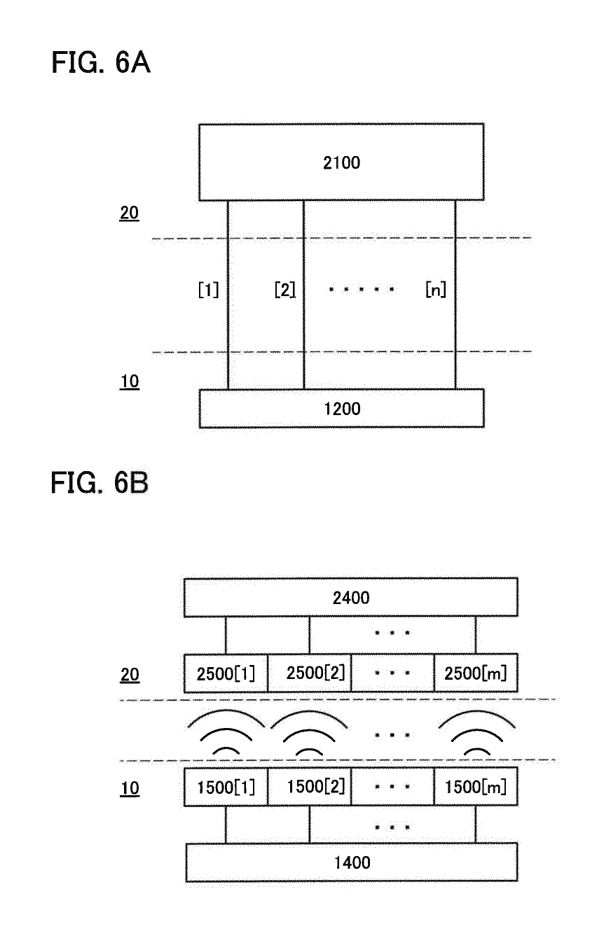

FIG. 6(A) is a diagram illustrating a configuration in which the number of wired transmission paths between the circuit 1200 and the circuit 2100 is plural. Note that solid lines connecting the circuit 1200 and the circuit 2100 illustrated in FIG. 6(A) can be cables with wired transmission paths, for example. Although one cable having one wired transmission path is described here, one cable may have a plurality of wired transmission paths. In addition, the configuration in which the circuit 1200 and the circuit 2100 are connected directly with the cables is illustrated in FIG. 6(A); however, another circuit, wiring, or the like may be provided between one end (a connection terminal) of the cable and the circuit 1200. The same applies to between the other end of the cable and the circuit 2100.

There is no upper limitation on the number of cables provided between the circuit 1200 and the circuit 2100. However, handling becomes difficult when there is a plurality of dedicated cables between the signal output device 10 and the display device 20; therefore, general-purpose cables which are connected to input/output ports are preferably used as the wired transmission paths.

Examples of the standard of the input/output ports provided in the signal output device 10 and the display device 20 include an USB, an HDMI (registered trademark), a D-sub, DVI, LVDS, Thunderbolt (registered trademark), and displayport. In addition, in addition, a port for optical communication (communication with optical fibers), a port for ISDN communication, a port for ADSL communication, and the like are also given. A port for power supply, a dedicated port for signal transmission, a port of a combination thereof, or the like can also be employed. Note that in the case where a port for power supply is used, a configuration in which the signal output device 10 and the display device 20 interchange power with each other or a configuration in which power can be supplied to one to the other, via a cable connected to the port can be employed.

In addition, not the above-described connection configuration of the cables via the ports but a configuration in which the circuit 1200 and the circuit 2100 are directly connected with cables may be employed. Alternatively, not the configuration of cables but a configuration of leads such as wirings of a printed board or a configuration of FPCs (Flexible printed circuits) may be employed. Furthermore, a terminal which obtains conduction by contact or the like may be provided between the circuit 1200 and the circuit 2100.

FIG. 6(B) is a diagram illustrating a configuration in which the number of wireless transmission paths between the circuit 1400 and the circuit 2400 is plural. In the case of using a plurality of wireless transmission paths, a configuration in which the number of frequency bands used for wireless transmission is plural and a configuration in which a plurality of channels is used in the same frequency band are given. For example, as the frequency band, the 2.4 GHz band and the 5 GHz band, which are used for Wi-Fi (registered trademark), can be used. In addition, 20 MHz and 40 MHz are used as the channel width in the 2.4 GHz band. Furthermore, 20 MHz, 40 MHz, 80 MHz, and 160 MHz are used as the channel width in the 5 GHz band. Alternatively, as a wireless mode, LTE (Long Term Evolution), TD-LTE, WiMAX (registered trademark), AXGP, CDMA, GSM, Bluetooth (registered trademark), or the like may be used.

Therefore, as illustrated in FIG. 6(B), it is effective that a plurality of antennas 1500 and a plurality of antennas 2500 are provided so as to correspond to a plurality of frequency bands. In addition, it is effective that a plurality of antennas is provided in the use of the same frequency band so as to correspond to a configuration in which a signal is divided and sent by the circuit 1400. For example, one to four antennas corresponding to the 2.4 GHz band can be provided. Alternatively, one to four antennas corresponding to the 5 GHz band can be provided. Alternatively, the antennas corresponding to the 2.4 GHz band and the antennas corresponding to the 5 GHz band whose total number is two to eight can be provided.

In addition, for the electric waves used in wireless transmission, the 2.5 GHz band, the 2.1 GHz band, the 1.8 GHz band, the 1.7 GHz band, the 1.5 GHz band, the 900 MHz band, the 800 MHz band, and the like which are used in mobile phones or the like may be used.

Note that although electric waves are used in wireless transmission in the above-described example, infrared light, visible light, ultraviolet light, or the like may be used for wireless transmission. In that case, the antennas 1500 may be replaced with transmitting devices such as light-emitting diodes. Alternatively, the antennas 2500 may be replaced with receiving devices such as photodiodes.

Note that FIG. 6(A) and FIG. 6(B) may be combined. In other words, the wired transmission illustrated in FIG. 6(A) and the wireless transmission illustrated in FIG. 6(B) may be combined and transmitted.

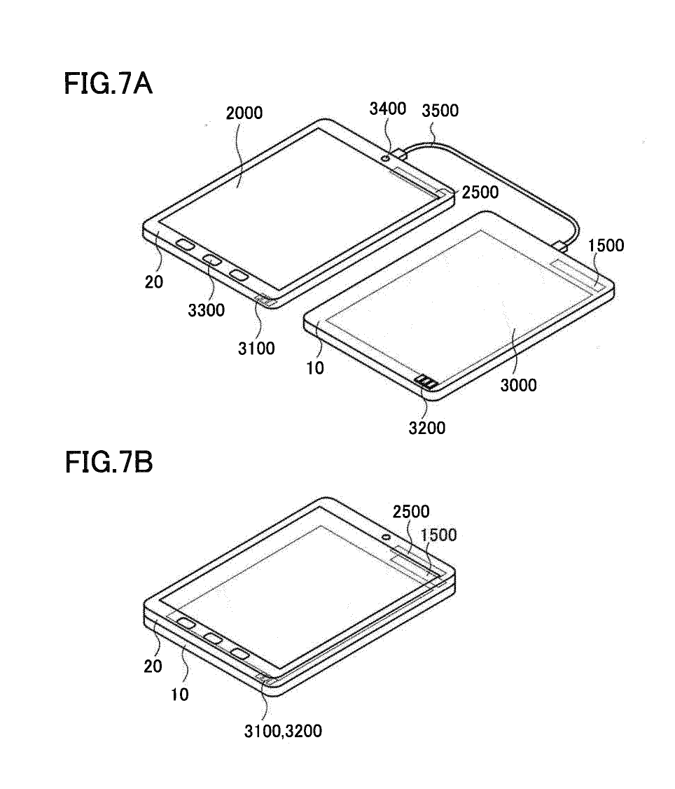

FIGS. 7(A) and (B) are diagrams illustrating specific examples of the signal output device 10, the display device 20, and the connection configuration thereof. The above-described circuit is not illustrated in the signal output device 10 and the display device 20 illustrated in FIGS. 7(A) and (B).

The signal output device 10 can include a battery 3000 and the antenna 1500 in its inside. In addition, it can include an input/output terminal 3200.

The display device 20 can include the display portion 2000, an input/output terminal 3100, an operation button 3300, a camera 3400, and the like. In addition, it can include the antenna 2500 in its inside.

In the example illustrated in FIG. 7(A), the signal output device 10 and the display device 20 are connected via input/output ports provided in both of them and a cable 3500. Owing to the cable 3500, in addition to the above-described transmission of signals, power can be supplied from the battery 3000 of the signal output device 10 to the display device 20. Furthermore, the transmission of signals can be performed between the antenna 1500 and the antenna 2500. In addition, charging may be performed wirelessly.

On the other hand, the example illustrated in FIG. 7(B) is an example in which the signal output device 10 and the display device 20 are located to overlap each other. In that case, the input/output terminal 3100 and the input/output terminal 3200 are in contact with each other, whereby a wired transmission path can be configured. That is, a structure without the cable 3500 can be obtained. In addition, since the antenna 1500 and the antenna 2500 are located to overlap each other, extremely high-speed communication is possible. Note that a configuration with a plurality of wired transmission paths can be obtained with the use of the cable 3500.

The structure described in this embodiment can be used in appropriate combination with the structure described in any of the other embodiments.

### Embodiment 2

In this embodiment, a transistor which can be used in the structures of the signal output device 10 and the display device 20 formed in Embodiment 1 is described.

As the transistor that can be used in one embodiment of the present invention, a transistor using an oxide semiconductor (hereinafter, an OS transistor) can be used.

An OS transistor has an extremely low off-state current. Therefore, for example, in the case where OS transistors are used as transistors of the signal output device 10 and a memory circuit included in the display device 20, a period during which charge can be held in a charge accumulation portion can be extremely long. Thus, the frequency of refresh of data written in the charge accumulation portion (FD) can be decreased, leading to a reduction in power consumption of the memory circuit. Furthermore, the memory circuit can also be used as a substantially non-volatile memory circuit.

When an OS transistor which has an extremely low leakage current in an off state is used as the transistor used in the pixel portion of the display device, the time for holding image signals can be extended. For example, images can be held even when the frequency of writing image signals is higher than or equal to 11.6 μHz (once a day) and less than 0.1 Hz (0.1 times a second), preferably higher than or equal to 0.28 mHz (once an hour) and less than 1 Hz (once a second). Thus, the frequency of writing image signals can be reduced. As a result, the power consumption of the display panel can be reduced. In addition, in an operation in which the number of writing image signals is reduced as described above, flicker on the screen can be prevented, leading to reduction of eye strain. In addition, in such a case, wireless transmission may be performed.

### <Components of Transistor Structure 1>

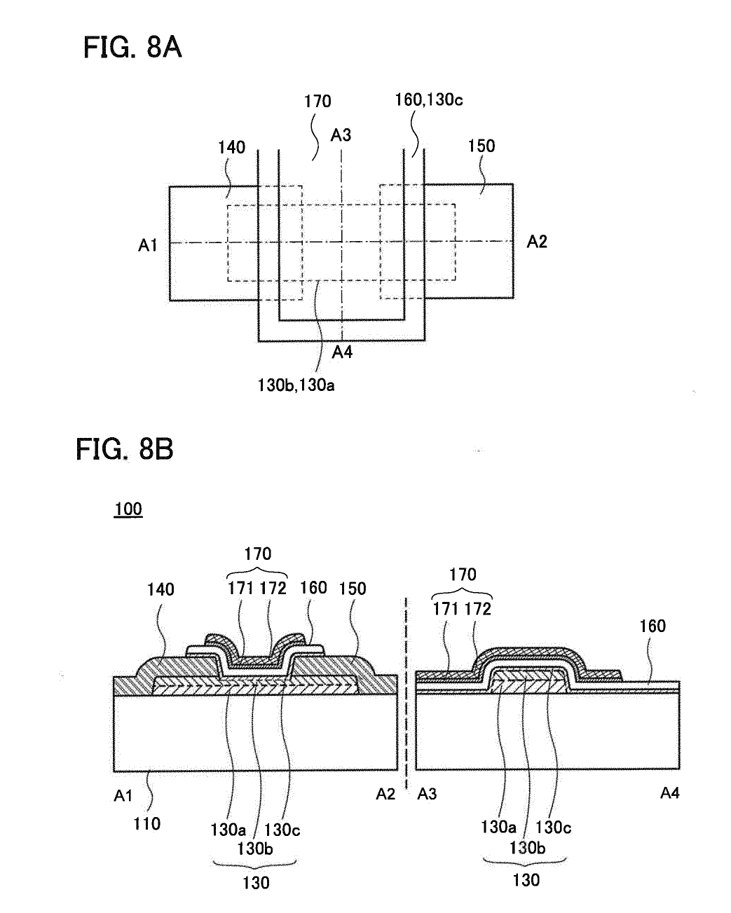

Examples of components of the transistor are described below. FIGS. 8(A) and 8(B) are a top view and a cross-sectional view of a transistor 100 according to one embodiment of the present invention. FIG. 8(A) is a top view and FIG. 8(B) is a cross-sectional view taken along dashed-dotted line A1-A2 and dashed-dotted line A3-A4 illustrated in FIG. 8(A). Note that for simplification of the drawing, some components in the top view in FIG. 8(A) are not illustrated.

The transistor 100 illustrated in FIG. 8(A) and FIG. 8(B) includes a substrate 110, an oxide semiconductor 130, a conductor 140, a conductor 150, an insulator 160, and a conductor 170.

As the substrate 110, a substrate that can withstand heat treatment performed later is used. For example, an insulator substrate, a semiconductor substrate, or a conductor substrate may be used. As the insulator substrate, a glass substrate, a quartz substrate, a sapphire substrate, or a stabilized zirconia substrate (an yttria-stabilized zirconia substrate or the like) is used, for example.

As the semiconductor substrate, a single material semiconductor substrate of silicon, germanium, or the like or a compound semiconductor substrate of silicon carbide, silicon germanium, gallium arsenide, indium phosphide, zinc oxide, gallium oxide, or the like is used, for example. A semiconductor substrate in which an insulator region is provided in the above semiconductor substrate, e.g., a silicon on insulator (SOI) substrate or the like is given.

As the conductor substrate, a graphite substrate, a metal substrate, an alloy substrate, or the like is given. A substrate including a metal nitride, a substrate including a metal oxide, or the like is given. An insulator substrate provided with a conductor or a semiconductor, a semiconductor substrate provided with a conductor or an insulator, a conductor substrate provided with a semiconductor or an insulator, or the like is given. Alternatively, any of these substrates over which an element is provided may be used. As the element provided over the substrate, a capacitor, a resistor, a switching element, a light-emitting element, a memory element, or the like is given.

A flexible substrate may be used as the substrate 110. As a method for providing the transistor over a flexible substrate, there is a method in which the transistor is formed over a non-flexible substrate and then the transistor is separated and transferred to the substrate 110 that is a flexible substrate. In that case, a separation layer is preferably provided between the non-flexible substrate and the transistor.

As the substrate 110, a sheet, a film, or a foil containing a fiber may be used. The substrate 110 may have elasticity. The substrate 110 may have a property of returning to its original shape when bending or pulling is stopped. Alternatively, it may have a property of not returning to its original shape. The thickness of the substrate 110 is, for example, greater than or equal to 5 μm and less than or equal to 700 Mm, preferably greater than or equal to 10 μm and less than or equal to 500 μm, further preferably greater than or equal to 15 μm and less than or equal to 300 μm.

For the substrate 110 that is a flexible substrate, for example, metal, an alloy, resin, glass, or fiber thereof can be used. The substrate 110 that is a flexible substrate preferably has a lower coefficient of linear expansion because deformation due to an environment is suppressed. For the substrate 110 that is a flexible substrate, for example, a material whose coefficient of linear expansion is lower than or equal to 1×10⁻³/K, lower than or equal to 5×10⁻⁵/K, or lower than or equal to 1×10⁻⁵/K may be used. Examples of the resin include polyester, polyolefin, polyamide (e.g., nylon or aramid), polyimide, polycarbonate, acrylic, and polytetrafluoroethylene (PTFE). In particular, aramid is preferable as the substrate 110 that is a flexible substrate because its coefficient of linear expansion is low.

Note that an insulator may be provided between the substrate 110 and the oxide semiconductor 130. Providing the insulator can prevent diffusion of impurities from the substrate 110. As the insulator, an single-layer or stacked-layer insulator including boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. As the insulator, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide can be used.

Since the oxide semiconductor 130 is an oxide, the insulator can play a role in supplying oxygen to the oxide semiconductor 130. Therefore, the insulator is preferably an insulator containing excess oxygen.

The insulator containing excess oxygen is an insulator from which oxygen is released by heat treatment, for example. For example, a silicon oxide layer containing excess oxygen is a silicon oxide layer which can release oxygen by heat treatment or the like. Therefore, the insulator is an insulator in which oxygen can be moved. In other words, the insulator may be an insulator having an oxygen-transmitting property. For example, the insulator may be an insulator having a higher oxygen-transmitting property than a semiconductor.

The insulator containing excess oxygen has a function of reducing oxygen vacancies in the oxide semiconductor 130 in some cases. In the oxide semiconductor 130, oxygen vacancies form deep states and serve as hole traps or the like. In addition, hydrogen comes into the site of an oxygen vacancy and forms an electron serving as a carrier in some cases. Therefore, by reducing the oxygen vacancies in the oxide semiconductor 130, stable electrical characteristics can be given to the transistor.

Here, as an insulator from which oxygen is released by heat treatment, it is preferable to use the one in which oxygen at greater than or equal to 1×10¹⁸ atoms/cm³, greater than or equal to 1×10¹⁹ atoms/cm³, or greater than or equal to 1×10²⁰ atoms/cm³ (converted into the number of oxygen atoms) can be observed in TDS analysis in the range of a surface temperature of the film of 100° C. to 700° C. or 100° C. to 500° C.

The insulator containing excess oxygen may be oxygen-excess silicon oxide (SiO_{X} (X>2)). In the oxygen-excess silicon oxide (SiO_{X} (X>2)), the number of oxygen atoms per unit volume is more than twice the number of silicon atoms per unit volume. The number of silicon atoms and the number of oxygen atoms per unit volume are measured by Rutherford backscattering spectrometry (RBS).

As the oxide semiconductor 130, an oxide semiconductor including a crystal is preferably used. FIG. 8 illustrates the case where the oxide semiconductor 130 is a stacked film in which an oxide semiconductor 130a, an oxide semiconductor 130b, and an oxide semiconductor 130c are stacked in this order.

The oxide semiconductor 130 is an oxide semiconductor containing indium, for example. The oxide semiconductor 130 has high carrier mobility (electron mobility) by containing indium, for example. The oxide semiconductor 130 preferably includes an element M. The element M is preferably aluminum, gallium, yttrium, tin, or the like. Other elements which can be used as the element M are boron, silicon, titanium, iron, nickel, germanium, zirconium, molybdenum, lanthanum, cerium, neodymium, hafnium, tantalum, tungsten, and the like.

Note that two or more of the above elements may be used in combination as the element M. The element M is an element having high bonding energy with oxygen, for example. The element M is an element whose bonding energy with oxygen is higher than that of indium, for example. The element M is an element that can increase the energy gap of the oxide semiconductor, for example. Further, the oxide semiconductor 130 preferably contains zinc. When the oxide semiconductor contains zinc, the oxide semiconductor is easily crystallized, in some cases.

Note that the oxide semiconductor 130 is not limited to the oxide semiconductor containing indium. The oxide semiconductor 130 may be, for example, an oxide semiconductor which does not contain indium and contains zinc, an oxide semiconductor which does not contain indium and contains gallium, or an oxide semiconductor which does not contain indium and contains tin, e.g., a zinc tin oxide, a gallium tin oxide, or gallium oxide.

The case where the oxide semiconductor 130a, the oxide semiconductor 130b, and the oxide semiconductor 130c include indium is described. Note that in the case where the oxide semiconductor 130a is an In-M-Zn oxide and the summation of In and M is set to be 100 atomic %, it is preferable that In be set to be less than 50 atomic % and M be set to be greater than 50 atomic %, further preferably In be set to be less than 25 atomic % and M be set to be greater than 75 atomic %.

In the case where the oxide semiconductor 130b is an In-M-Zn oxide and the summation of In and M is set to be 100 atomic %, it is preferable that In be set to be greater than 25 atomic % and M be set to be less than 75 atomic %, further preferably In be set to be greater than 34 atomic % and M be set to be less than 66 atomic %.

In the case where the oxide semiconductor 130c is an In-M-Zn oxide and the summation of In and M is set to be 100 atomic %, it is preferable that In be set to be less than 50 atomic % and M be set to be greater than 50 atomic %, further preferably In be set to be less than 25 atomic % and M be set to be greater than 75 atomic %. Note that the oxide semiconductor 130c may be an oxide that is a type the same as that of the oxide semiconductor 130a.

As the oxide semiconductor 130b, an oxide having an electron affinity higher than those of the oxide semiconductor 130a and the oxide semiconductor 130c is used. For example, as the oxide semiconductor 130b, an oxide having an electron affinity larger than those of the oxide semiconductor 130a and the oxide semiconductor 130c by 0.07 eV or higher and 1.3 eV or lower, preferably 0.1 eV or higher and 0.7 eV or lower, and further preferably 0.15 eV or higher and 0.4 eV or lower is used. Note that the electron affinity refers to an energy difference between the vacuum level and the conduction band minimum.

An indium gallium oxide has a small electron affinity and an excellent oxygen-blocking property. Therefore, the oxide semiconductor 130c preferably includes an indium gallium oxide. The gallium atomic ratio [Ga/(In+Ga)] is, for example, higher than or equal to 70%, preferably higher than or equal to 80%, further preferably higher than or equal to 90%.

Note that the oxide semiconductor 130a and/or the oxide semiconductor 130c may be gallium oxide. For example, when gallium oxide is used for the oxide semiconductor 130c, a leakage current generated between the conductor 140 or the conductor 150 and the conductor 170 can be reduced. In other words, the off-state current of the transistor can be reduced.

At this time, when a gate voltage is applied, a channel is formed in the oxide semiconductor 130b, which has the largest electron affinity among the oxide semiconductor 130a, the oxide semiconductor 130b, and the oxide semiconductor 130c. Therefore, the oxide semiconductor 130b can be regarded as having a region serving as a semiconductor, while the oxide semiconductor 130a and the oxide semiconductor 130c can be regarded as having a region serving as an insulator or a semi-insulator.

Note that the thickness of the oxide semiconductor 130c is preferably as small as possible to increase the on-state current of the transistor. For example, a form including a region of less than 10 nm, preferably less than or equal to 5 nm, further preferably less than or equal to 3 nm is employed. Meanwhile, the oxide semiconductor 130c has a function of blocking entry of elements other than oxygen (such as hydrogen and silicon) included in the adjacent insulator into the oxide semiconductor 130b where a channel is formed. For this reason, it is preferable that the oxide semiconductor 130c have a certain thickness. For example, the oxide semiconductor 130c has a form including a region with a thickness of greater than or equal to 0.3 nm, preferably greater than or equal to 1 nm, further preferably greater than or equal to 2 nm. The oxide semiconductor 130c preferably has an oxygen-blocking property to suppress outward diffusion of oxygen released from the substrate 110, or an insulator or the like between the substrate 110 and the oxide semiconductor 130.

To increase the reliability, it is preferable to increase the thickness of the oxide semiconductor 130a. For example, the oxide semiconductor 130a has a form including a region with a thickness of greater than or equal to 10 nm, preferably greater than or equal to 20 nm, further preferably greater than or equal to 40 nm, still further preferably greater than or equal to 60 nm. Increasing the thickness of the oxide semiconductor 130a can increase the distance from the substrate 110 or an insulator provided over the substrate 110 to the oxide semiconductor 130b in which the channel is formed. Since the productivity of the semiconductor device including the transistor might be decreased, the oxide semiconductor 130a has a form including a region with a thickness, for example, less than or equal to 200 nm, preferably less than or equal to 120 nm, or further preferably less than or equal to 80 nm.

For example, silicon in the oxide semiconductor might serve as a carrier trap or a carrier generation source. Therefore, the silicon concentration of the oxide semiconductor 130b is preferably as low as possible. For example, a region with a low silicon concentration is preferably provided between the oxide semiconductor 130b and the oxide semiconductor 130c in an analysis using secondary ion mass spectrometry (SIMS). The silicon concentration is lower than 1×10¹⁹ atoms/cm³, preferably lower than 5×10¹⁸ atoms/cm³, further preferably lower than 2×10¹⁸ atoms/cm³.

In addition, a region with a low silicon concentration is preferably provided between the oxide semiconductor 130b and the oxide semiconductor 130c. The silicon concentration is lower than 1×10¹⁹ atoms/cm³, preferably lower than 5×10¹⁸ atoms/cm³, further preferably lower than 2×10¹⁸ atoms/cm³.

When hydrogen contained in the oxide semiconductor 130b as an impurity moves to the surface of the semiconductor and bonds to oxygen in the vicinity of the surface to form a water molecule, which is released from the surface in some cases. At this time, oxygen vacancy V_{O} is formed at the position of O released as a water molecule. For that reason, it is preferable that the hydrogen concentration of the oxide semiconductor 130b be sufficiently reduced. Therefore, in the oxide semiconductor 130b, water molecules measured by TDS analysis at a substrate surface temperature ranging from 100° C. to 700° C. or 100° C. to 500° C. is less than or equal to 1.0×10²¹/cm³ (1.0/nm³), preferably less than or equal to 1.0×10²⁰/cm³ (0.1/nm³).

Note that it hydrogen as an impurity in the semiconductor does not necessarily exist as a water molecule because it is in a state of a hydrogen atom, a hydrogen ion, a hydrogen molecule, a hydroxy group, a hydroxide ion, and the like.

To reduce the hydrogen concentration of the oxide semiconductor 130b, the hydrogen concentrations of the oxide semiconductor 130a and the oxide semiconductor 130c are also preferably reduced. In the oxide semiconductor 130a and the oxide semiconductor 130c, water molecules measured by TDS analysis at a substrate surface temperature ranging from 100° C. to 700° C. or 100° C. to 500° C. is less than or equal to 1.0×10²¹/cm³ (1.0/nm³), preferably less than or equal to 1.0×10²⁰/cm³ (0.1/nm³).

When an oxide semiconductor including a crystal with sufficiently reduced hydrogen concentration is used for a channel formation region in a transistor, stable electrical characteristics can be given. That is, a change in electrical characteristics can be inhibited and reliability can be improved. Further, a semiconductor device with reduced power consumption can be provided.

Note that when copper enters the oxide semiconductor, an electron trap might be generated. The electron trap might shift the threshold voltage of the transistor in the positive direction. Therefore, the copper concentration on the surface of or in the oxide semiconductor 130b is preferably as low as possible. For example, the oxide semiconductor 130b preferably has a region in which the copper concentration is lower than or equal to 1×10¹⁹ atoms/cm³, lower than or equal to 5×10¹⁸ atoms/cm³, or lower than or equal to 1×10¹⁸ atoms/cm³.

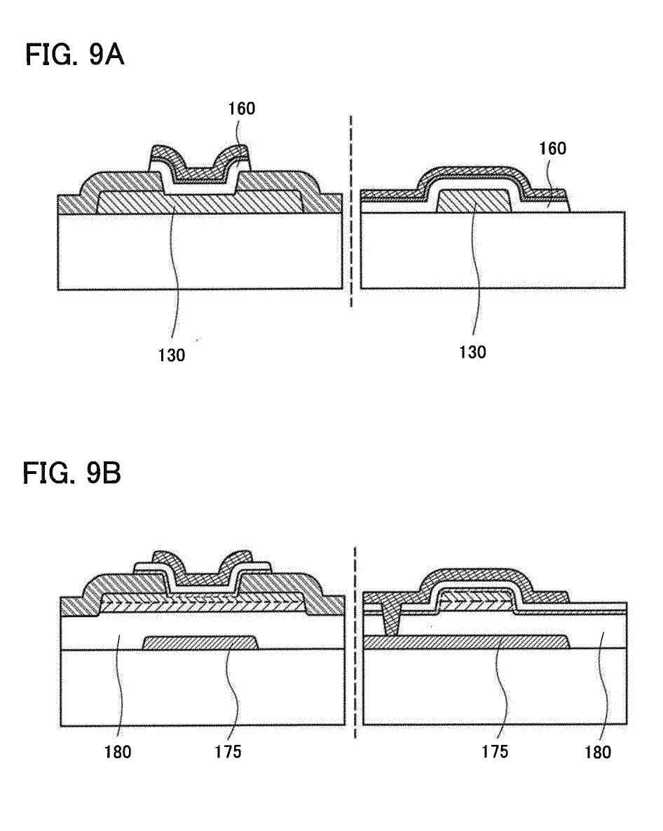

Note that the above-described structure in which the oxide semiconductor 130 includes three layers is an example. For example, a single layer may be used instead of a stacked layer structure as illustrated in FIG. 9(A). Alternatively, a two-layer structure without the oxide semiconductor 130a or the oxide semiconductor 130c may be employed. Further alternatively, a four-layer structure in which any one of the semiconductors described as examples of the oxide semiconductor 130a, the oxide semiconductor 130b, and the oxide semiconductor 130c is provided below or over the oxide semiconductor 130a or below or over the oxide semiconductor 130c may be employed. Further alternatively, an n-layer structure (n is an integer of 5 or more) in which any one of the semiconductors described as examples of the oxide semiconductor 130a, the oxide semiconductor 130b, and the oxide semiconductor 130c is provided in two or more of the following positions: over the oxide semiconductor 130a, below the oxide semiconductor 130a, over the oxide semiconductor 130c, and below the oxide semiconductor 130c.

As the conductor 140 and the conductor 150, a single-layer or a stacked-layer conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten may be used. The conductor 140 and the conductor 150 may be an alloy film or a compound film, and a conductor containing aluminum, a conductor containing copper and titanium, a conductor containing copper and manganese, a conductor containing indium, tin, and oxygen, a conductor containing titanium and nitrogen, or the like may be used.

As the insulator 160, a single-layer or stacked-layer insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum may be used. As the insulator 160, for example, aluminum oxide, magnesium oxide, silicon oxide, silicon oxynitride, silicon nitride oxide, silicon nitride, gallium oxide, germanium oxide, yttrium oxide, zirconium oxide, lanthanum oxide, neodymium oxide, hafnium oxide, or tantalum oxide may be used.

As the conductor 170, a single-layer or stacked-layer conductor containing one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, platinum, silver, indium, tin, tantalum, and tungsten may be used. Although a stacked-layer structure of the conductor 171 and the conductor 172 is employed in the drawing, the structure may be determined as appropriate. For example, an alloy film or a compound film may be used, and a conductor containing aluminum, a conductor containing copper and titanium, a conductor containing copper and manganese, a conductor containing indium, tin, and oxygen, a conductor containing titanium and nitrogen, or the like may be used.

As illustrated in FIG. 9(A), the insulator 160 may be formed using the conductor 170 as a mask. Alternatively, the conductor 170 and the insulator 160 may be formed using the same resist mask. The use of the same resist mask can reduce lithography steps and reduce manufacturing costs.

### <Modification Example of Transistor Structure 1>

The transistor according to one embodiment of the present invention may include a conductor 175 between the substrate 110 and an insulator 180 as illustrated in FIG. 9(B). The conductor 175 has a function of a second gate electrode (also referred to as a bottom gate electrode) of the transistor.

For example, a voltage which is the same as that applied to the conductor 170 can be applied to the conductor 175. Thus, an electric field can be applied from upper and lower sides of the oxide semiconductor 130, resulting in increased on-state current of the transistor. In addition, the off-state current of the transistor can be reduced. For example, by applying a lower voltage or a higher voltage than a source electrode to the conductor 175, the threshold voltage of the transistor may be shifted in the positive direction or the negative direction. For example, by shifting the threshold voltage of the transistor in the positive direction, normally off in which the transistor is in a non-conduction state (off state) even when the gate voltage is 0 V can be achieved in some cases. The voltage applied to the conductor 175 may be variable or fixed. When the voltage applied to the conductor 175 is a variable, a circuit for controlling the voltage may be electrically connected to the conductor 175.

As the conductor 175, a single-layer or stacked-layer conductor containing, for example, one or more kinds of boron, nitrogen, oxygen, fluorine, silicon, phosphorus, aluminum, titanium, chromium, manganese, cobalt, nickel, copper, zinc, gallium, yttrium, zirconium, molybdenum, ruthenium, silver, indium, tin, tantalum, and tungsten may be used. For example, an alloy film or a compound film may be used, and a conductor containing aluminum, a conductor containing copper and titanium, a conductor containing copper and manganese, a conductor containing indium, tin, and oxygen, a conductor containing titanium and nitrogen, or the like may be used.

### <Transistor Structure 2>

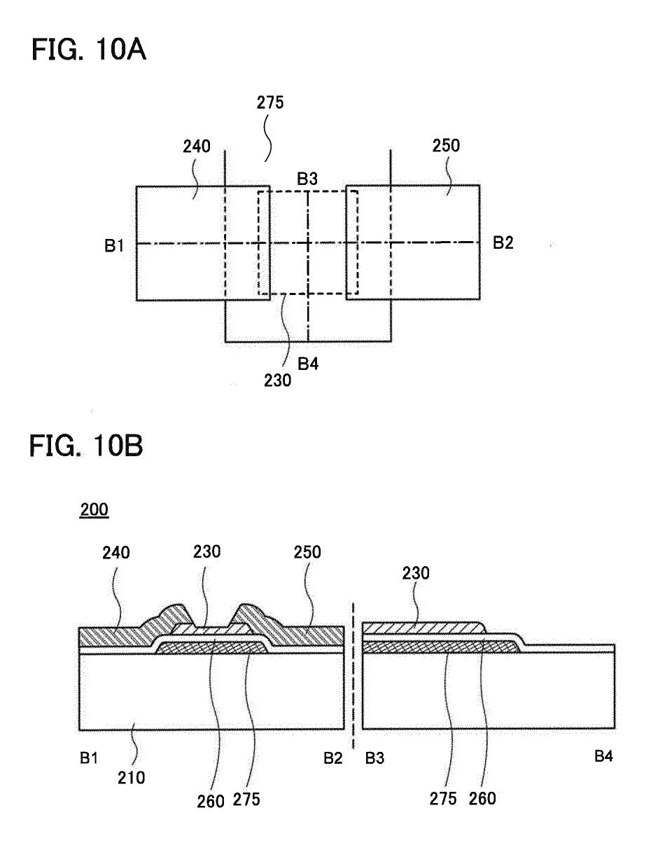

The transistor according to one embodiment of the present invention may have a structure illustrated in FIG. 10(A) and FIG. 10(B). FIG. 10(A) and FIG. 10(B) are a top view and a cross-sectional view of a transistor 200. FIG. 10(A) is a top view and FIG. 10(B) is a cross-sectional view taken along dashed-dotted line B1-B2 and dashed-dotted line B3-B4 in FIG. 10(A). Note that for simplification of the drawing, some components are not illustrated in the top view of FIG. 10(A).

The transistor 200 illustrated in FIG. 10(A) and FIG. 10(B) includes a substrate 210, a conductor 275 over the substrate 210, an insulator 260 over the conductor 275, a semiconductor 230 over the insulator 260, and a conductor 240 and a conductor 250 which are in contact with the top surface of the semiconductor 230 and spaced apart. Note that the conductor 275 includes a region over which the semiconductor 230 is positioned with the insulator 260 provided therebetween. Note that an insulator may be provided between the substrate 210 and the conductor 275.

The semiconductor 230 has a function of a channel formation region of the transistor 200. The conductor 275 has a function of a first gate electrode (also referred to as a front gate electrode) of the transistor 200. The insulator 260 has a function of a gate insulator of the transistor 200. The conductor 240 and the conductor 250 have functions of the source electrode and the drain electrode of the transistor.

The insulator 260 is preferably an insulator containing excess oxygen.

For the substrate 210, the description of the substrate 110 can be referred to. For the conductor 275, the description of the conductor 170 can be referred to. For the insulator 260, the description of the insulator 160 can be referred to. For the semiconductor 230, the description of the oxide semiconductor 130 can be referred to. For the conductor 240 and the conductor 250, the description of the conductor 140 and the conductor 150 can be referred to.

### <Transistor Structure 3>

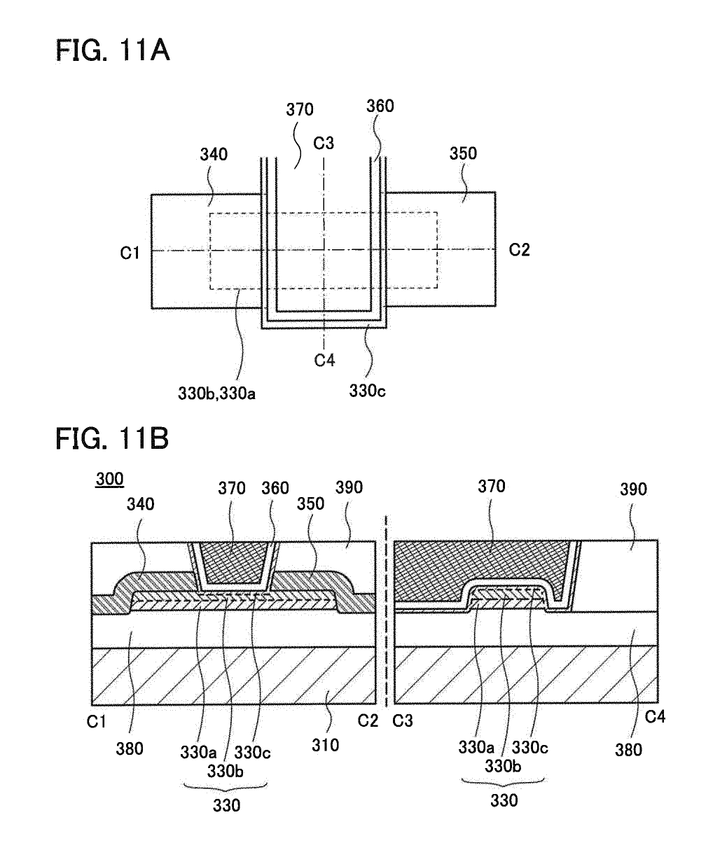

The transistor according to one embodiment of the present invention may have a structure illustrated in FIG. 11(A) and FIG. 46(B). FIG. 11(A) and FIG. 11(B) are a top view and a cross-sectional view of a transistor 300. FIG. 11(A) is a top view and FIG. 11(B) is a cross-sectional view taken along dashed-dotted line B1-B2 and dashed-dotted line B3-B4 in FIG. 11(A). Note that for simplification of the drawing, some components are not illustrated in the top view of FIG. 11(A).

The transistor 300 illustrated in FIG. 11(A) and FIG. 11(B) includes a substrate 310, an insulator 380 over the substrate 310, a semiconductor 330 (a semiconductor 330a, a semiconductor 330b, and a semiconductor 330c) over the insulator 380, a conductor 340 and a conductor 350 which are in contact with the semiconductor 330 and spaced apart, an insulator 360 in contact with the semiconductor 330c, and a conductor 370 in contact with the insulator 360. Note that the semiconductor 330, the insulator 360, and the conductor 370 are provided in an opening that is provided in an insulator 390 over the transistor 300 and reaches the semiconductor 330a, the semiconductor 330b, and the insulator 380.

The semiconductor 330 has a function of a channel formation region of the transistor 300. The conductor 370 has a function of a gate electrode of the transistor 300. The insulator 360 has a function of a gate insulator of the transistor 300. The conductor 340 and the conductor 350 have functions of a source electrode and a drain electrode of the transistor.

The insulator 360 is preferably an insulator containing excess oxygen.

For the substrate 310, the description of the substrate 110 can be referred to. For the conductor 370, the description of the conductor 170 can be referred to. For the insulator 360, the description of the insulator 160 can be referred to. For the semiconductor 330, the description of the oxide semiconductor 130 can be referred to. For the conductor 340 and the conductor 350, the description of the conductor 140 and the conductor 150 can be referred to.

In the structure of the transistor 300, a region in which a conductor serving as a source electrode or a drain electrode and a conductor serving as a gate electrode overlap each other is smaller than those of the other transistor structures described above; thus, the parasitic capacitance can be reduced. Therefore, the transistor 300 is preferable as a component of a circuit which is used in an arithmetic device, a memory device, or the like and for which high-speed operation is needed. As illustrated in the drawing, a top surface of the transistor 300 is preferably planarized by a CMP (Chemical Mechanical Polishing) method or the like, but is not necessarily planarized.

Furthermore, this embodiment can be applied to a transistor of various types. Depending on circumstances or conditions, the transistor can be a planar-type transistor, a fin-type transistor, or a tri-gate transistor, for example. In addition, it can also be applied to a transistor having a structure in which a gate electrode electrically surrounds a semiconductor in the channel width direction with a gate insulator interposed therebetween (surrounded channel (s-channel) structure). With an s-channel structure, a transistor having high on-state current can be obtained.

Note that the structure of the transistor in this embodiment is an example. Therefore, for example, one or more of the transistors 100 to 300 can be formed using a transistor in which an active region or an active layer includes silicon, germanium, silicon germanium, silicon carbide, gallium arsenide, aluminum gallium arsenide, indium phosphide, gallium nitride, an organic semiconductor, or the like.

The structure described in this embodiment can be used in appropriate combination with the structure described in any of the other embodiments.

### Embodiment 3

A structure of an oxide semiconductor film which can be used for one embodiment of the present invention is described below.

In this specification, “parallel” indicates that the angle formed between two straight lines is greater than or equal to −10° and less than or equal to 100, and accordingly, it also includes the case where the angle is greater than or equal to −5° and less than or equal to 5°. In addition, “perpendicular” indicates that the angle formed between two straight lines is greater than or equal to 80° and less than or equal to 100°, and accordingly, it also includes the case where the angle is greater than or equal to 85° and less than or equal to 95°.

In this specification, trigonal and rhombohedral crystal systems are included in a hexagonal crystal system.

An oxide semiconductor film is classified roughly into a single-crystal oxide semiconductor film and a non-single-crystal oxide semiconductor film. The non-single-crystal oxide semiconductor film includes any of a CAAC-OS (C Axis Aligned Crystalline Oxide Semiconductor) film, a polycrystalline oxide semiconductor film, a microcrystalline oxide semiconductor film, an amorphous oxide semiconductor film, and the like.

First, a CAAC-OS film will be described.

The CAAC-OS film is one of oxide semiconductor films having a plurality of c-axis aligned crystal parts.

In a combined analysis image (also referred to as a high-resolution TEM image) of a bright-field image and a diffraction pattern of a CAAC-OS film, which is obtained using a transmission electron microscope (TEM), a plurality of crystal parts can be observed. However, in the high-resolution TEM image, a boundary between crystal parts, that is, a grain boundary is not clearly observed. Thus, in the CAAC-OS film, a reduction in electron mobility due to the grain boundary is less likely to occur.

According to the high-resolution cross-sectional TEM image of the CAAC-OS film observed in a direction substantially parallel to a sample surface, metal atoms are arranged in a layered manner in the crystal parts. Each metal atom layer has a morphology reflecting unevenness of a surface where the CAAC-OS film is formed (hereinafter, a surface where the CAAC-OS film is formed is also referred to as a formation surface) or a top surface of the CAAC-OS film, and is arranged parallel to the formation surface or the top surface of the CAAC-OS film.

On the other hand, according to the high-resolution planar TEM image of the CAAC-OS film observed in a direction substantially perpendicular to the sample surface, metal atoms are arranged in a triangular or hexagonal configuration in the crystal parts. However, there is no regularity of arrangement of metal atoms between different crystal parts.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 310. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

Note that when the CAAC-OS film with an InGaZnO₄ crystal is analyzed by an out-of-plane method, a peak may also be observed when 2θ is around 36°, in addition to the peak at 2θ of around 31°. The peak at 2θ of around 36° indicates that a crystal having no c-axis alignment is included in part of the CAAC-OS film. It is preferable that in the CAAC-OS film, a peak appear when 2θ is around 31 and that a peak not appear when 2θ is around 36°.

The CAAC-OS film is an oxide semiconductor film having low impurity concentration. The impurity is an element other than the main components of the oxide semiconductor film, such as hydrogen, carbon, silicon, or a transition metal element. In particular, an element that has higher bonding strength to oxygen than a metal element included in the oxide semiconductor film, such as silicon, disturbs the atomic arrangement of the oxide semiconductor film by depriving the oxide semiconductor film of oxygen and causes a decrease in crystallinity. Further, a heavy metal such as iron or nickel, argon, carbon dioxide, or the like has a large atomic radius (molecular radius), and thus disturbs the atomic arrangement of the oxide semiconductor film and causes a decrease in crystallinity when it is contained in the oxide semiconductor film. Note that the impurity contained in the oxide semiconductor film might serve as a carrier trap or a carrier generation source.

The CAAC-OS film is an oxide semiconductor film having a low density of defect states. In some cases, oxygen vacancies in the oxide semiconductor film serve as carrier traps or serve as carrier generation sources when hydrogen is captured therein.

The state in which impurity concentration is low and density of defect states is low (the number of oxygen vacancies is small) is referred to as a highly purified intrinsic or substantially highly purified intrinsic state. A highly purified intrinsic or substantially highly purified intrinsic oxide semiconductor film has few carrier generation sources, and thus can have a low carrier density. Therefore, a transistor including the oxide semiconductor film rarely has negative threshold voltage (is rarely normally on). The highly purified intrinsic or substantially highly purified intrinsic oxide semiconductor film has few carrier traps. Accordingly, the transistor including the oxide semiconductor film has little variation in electrical characteristics and high reliability. Electric charge trapped by the carrier traps in the oxide semiconductor film takes a long time to be released and might behave like fixed electric charge. Thus, the transistor including the oxide semiconductor film having high impurity concentration and a high density of defect states has unstable electrical characteristics in some cases.

With the use of the CAAC-OS film in a transistor, variation in the electrical characteristics of the transistor due to irradiation with visible light or ultraviolet light is small.

Next, a microcrystalline oxide semiconductor film will be described.

A microcrystalline oxide semiconductor film has a region in which a crystal part is observed and a region in which a crystal part is not clearly observed in a high-resolution TEM image. In most cases, the size of a crystal part included in the microcrystalline oxide semiconductor film is greater than or equal to 1 nm and less than or equal to 100 nm, or greater than or equal to 1 nm and less than or equal to 10 nm. An oxide semiconductor film including a nanocrystal (nc) that is a microcrystal with a size greater than or equal to 1 nm and less than or equal to 10 nm, or a size greater than or equal to 1 nm and less than or equal to 3 nm is referred to as an nc-OS (nanocrystalline Oxide Semiconductor) film. In a high-resolution TEM image of the nc-OS film, for example, a grain boundary is not clearly observed in some cases.

In the nc-OS film, a microscopic region (for example, a region with a size greater than or equal to 1 nm and less than or equal to 10 nm, in particular, a region with a size greater than or equal to 1 nm and less than or equal to 3 nm) has a periodic atomic arrangement. There is no regularity of crystal orientation between different crystal parts in the nc-OS film. Thus, the orientation of the whole film is not observed. Accordingly, in some cases, the nc-OS film cannot be distinguished from an amorphous oxide semiconductor film depending on an analysis method. For example, when the nc-OS film is subjected to structural analysis by an out-of-plane method with an XRD apparatus using an X-ray having a diameter larger than the size of a crystal part, a peak indicating a crystal plane does not appear. Further, a halo pattern is shown in a selected-area electron diffraction pattern of the nc-OS film obtained by using an electron beam having a probe diameter (e.g., 50 nm or larger) larger than the size of a crystal part. Meanwhile, spots are shown in a nanobeam electron diffraction pattern of the nc-OS film obtained by using an electron beam having a probe diameter close to or smaller than the size of a crystal part. Furthermore, in a nanobeam electron diffraction pattern of the nc-OS film, regions with high luminance in a circular (ring) pattern are shown in some cases. Moreover, in a nanobeam electron diffraction pattern of the nc-OS film, a plurality of spots are shown in a ring-like region in some cases.

The nc-OS film is an oxide semiconductor film that has high regularity as compared with an amorphous oxide semiconductor, film. Therefore, the nc-OS film has a lower density of defect states than an amorphous oxide semiconductor film. Note that there is no regularity of crystal orientation between different crystal parts in the nc-OS film. Therefore, the nc-OS film has a higher density of defect states than the CAAC-OS film.

Next, an amorphous oxide semiconductor film is described.

The amorphous oxide semiconductor film has disordered atomic arrangement and no crystal part. For example, the amorphous oxide semiconductor film does not have a specific state as in quartz.

In a high-resolution TEM image of the amorphous oxide semiconductor film, crystal parts cannot be found.

When the amorphous oxide semiconductor film is subjected to structural analysis by an out-of-plane method with an XRD apparatus, a peak which shows a crystal plane does not appear. A halo pattern is observed when the amorphous oxide semiconductor film is subjected to electron diffraction. Furthermore, a spot is not observed and a halo pattern appears when the amorphous oxide semiconductor film is subjected to nanobeam electron diffraction.

Note that an oxide semiconductor film may have a structure having physical properties intermediate between the nc-OS film and the amorphous oxide semiconductor film. The oxide semiconductor film having such a structure is specifically referred to as an amorphous-like oxide semiconductor (a-like OS) film.

In a high-resolution TEM image of the a-like OS film, a void may be observed. Furthermore, in the high-resolution TEM image, there are a region where a crystal part is clearly observed and a region where a crystal part is not observed. In some cases, growth of the crystal part occurs due to the crystallization of the a-like OS film, which is induced by a slight amount of electron beam employed in the TEM observation. In contrast, in the nc-OS film that has good quality, crystallization hardly occurs by a slight amount of electron beam used for TEM observation.

Note that the crystal part size in the a-like OS film and the nc-OS film can be measured using high-resolution TEM images. For example, an InGaZnO₄ crystal has a layered structure in which two Ga—Zn—O layers are included between In—O layers. A unit cell of the InGaZnO₄ crystal has a structure in which nine layers including three In—O layers and six Ga—Zn—O layers are stacked in the c-axis direction. Accordingly, the distance between the adjacent layers is equivalent to the lattice spacing on the (009) plane (also referred to as d value). The value is calculated to be 0.29 nm from crystal structural analysis. Thus, focusing on lattice fringes in the high-resolution TEM image, each of lattice fringes in which the lattice spacing therebetween is greater than or equal to 0.28 nm and less than or equal to 0.30 nm corresponds to the a-b plane of the InGaZnO₄ crystal.

Note that an oxide semiconductor film may be a stacked film including two or more films of an amorphous oxide semiconductor film, an a-like OS film, a microcrystalline oxide semiconductor film, and a CAAC-OS film, for example.

The structure described in this embodiment can be used in appropriate combination with the structure described in any of the other embodiments.

### Embodiment 4

In this embodiment, an example of a circuit which forms a semiconductor device included in an electronic device of one embodiment of the present invention is described with reference to drawings.

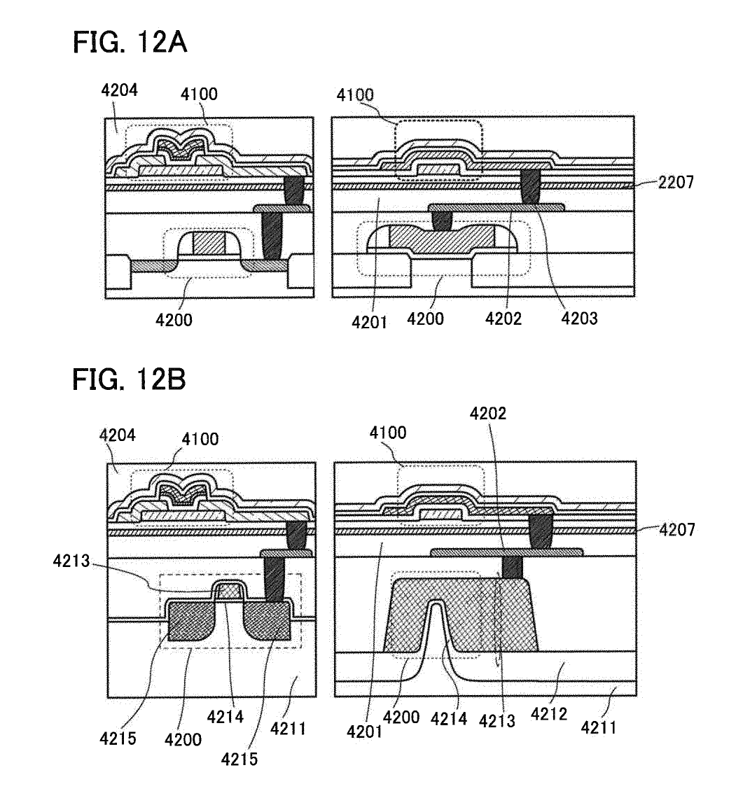

FIG. 12(A) illustrates a cross-sectional view of a circuit which forms a semiconductor device included in an electronic device of one embodiment of the present invention. The circuit illustrated in FIG. 12(A) includes a transistor 4200 using a first semiconductor material in a lower portion and includes a transistor 4100 using a second semiconductor material in an upper portion. Note that the left view illustrates a cross section of the transistors in the channel length direction, and the right view is a cross section in the channel width direction.

Note that a structure in which the transistor 4100 is provided with a bottom gate may be employed.

The first semiconductor material and the second semiconductor material are preferably materials which have different energy gaps. For example, the first semiconductor material can be a semiconductor material other than an oxide semiconductor (silicon (including strained silicon), germanium, silicon germanium, silicon carbide, gallium arsenide, aluminum gallium arsenide, indium phosphide, gallium nitride, an organic semiconductor or the like), and the second semiconductor material can be an oxide semiconductor. A transistor using a material other than an oxide semiconductor, such as single crystal silicon, can operate at high speed easily. In contrast, a transistor including an oxide semiconductor has low off-state current.

The transistor 4200 may be either an n-channel transistor or a p-channel transistor, a transistor appropriate for an intended circuit is used. Furthermore, the specific structure of the semiconductor device, such as the material or the structure used for the semiconductor device, is not necessarily limited to those described here except for the use of the transistor of one embodiment of the present invention which includes an oxide semiconductor.

FIG. 12(A) illustrates a structure in which the transistor 4100 is provided over the transistor 4200 with an insulating film 4201 and an insulating film 4207 provided therebetween. A plurality of wirings 4202 are provided between the transistor 4200 and the transistor 4100. Furthermore, wirings and electrodes provided over and under the layers are electrically connected to each other through a plurality of plugs 4203 embedded in the insulating films. An interlayer insulating film 4204 covering the transistor 4100 is provided.

Since the two kinds of transistors are stacked, the area occupied by the circuit can be reduced, allowing a plurality of circuits to be arranged at high density.

Here, in the case where a silicon-based semiconductor material is used for the transistor 4200 provided in a lower layer, hydrogen in an insulating film provided in the vicinity of the semiconductor film of the transistor 4200 terminates dangling bonds of silicon, providing an effect of improving the reliability of the transistor 4200. Meanwhile, in the case where an oxide semiconductor is used for the transistor 4100 provided in an upper layer, hydrogen in an insulating film provided in the vicinity of the semiconductor film of the transistor 4100 becomes a factor of generating carriers in the oxide semiconductor, which might cause reduction in the reliability of the transistor 4100. Therefore, in the case where the transistor 4100 using an oxide semiconductor is provided over the transistor 4200 using a silicon-based semiconductor material, it is particularly effective that the insulating film 4207 having a function of preventing diffusion of hydrogen is provided between them. The insulating film 4207 makes hydrogen remain in the lower layer, thereby improving the reliability of the transistor 4200. In addition, hydrogen is prevented from diffusing from the lower layer into the upper layer, whereby the reliability of the transistor 4100 can also be improved.

The insulating film 4207 can be formed using, for example, aluminum oxide, aluminum oxynitride, gallium oxide, gallium oxynitride, yttrium oxide, yttrium oxynitride, hafnium oxide, hafnium oxynitride, or yttria-stabilized zirconia (YSZ).

Furthermore, a blocking film having a function of preventing entry of hydrogen may be formed over the transistor 4100 so as to cover the transistor 4100 including an oxide semiconductor film. For the blocking film, a material that is similar to that of the insulating film 4207 can be used, and in particular, aluminum oxide is preferably used. The aluminum oxide film has a high shielding (blocking) effect of preventing penetration of both oxygen and impurities such as hydrogen and moisture. Thus, by using the aluminum oxide film as the blocking film covering the transistor 4100, release of oxygen from the oxide semiconductor film included in the transistor 4100 and entry of water and hydrogen into the oxide semiconductor film can be prevented.

Note that the transistor 4200 can be a transistor of various types without being limited to a planar type transistor. For example, a fin-type transistor, a tri-gate transistor, or the like can be employed. An example of a cross-sectional view in this case is shown in FIG. 12(B). An insulating film 4212 is provided over a semiconductor substrate 4211. The semiconductor substrate 4211 has a projecting portion with a thin tip (also referred to as a fin). Note that an insulating film may be provided over the projecting portion. The insulating film functions as a mask for preventing the semiconductor substrate 4211 from being etched when the projecting portion is formed. The projecting portion does not necessarily have the thin tip; a cuboid-like projecting portion and a projecting portion with a thick tip are permitted, for example. A gate insulating film 4214 is provided over the projecting portion of the semiconductor substrate 4211, and a gate electrode 4213 is provided thereover. Although the electrode 4213 has a single-layer structure in this embodiment, and a stack of two or more layers may be employed. Source and drain regions 4215 are formed in the semiconductor substrate 4211. Note that here is shown an example in which the semiconductor substrate 4211 includes the projecting portion; however, a semiconductor device of one embodiment of the present invention is not limited thereto. For example, a semiconductor region having a projecting portion may be formed by processing an SOI substrate.

Note that when a connection between the electrodes of the transistor 4100 and the transistor 4200 is changed from that in the above configuration, a variety of circuits can be formed. Examples of circuit configurations which can be achieved by using the semiconductor device of one embodiment of the present invention will be described below.

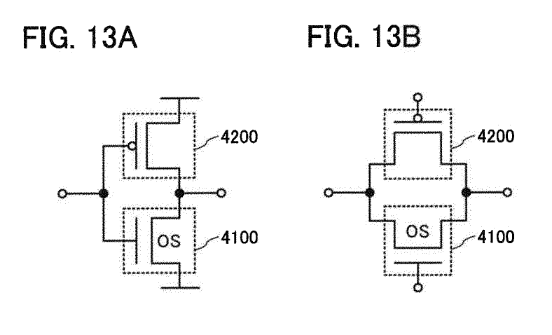

A circuit diagram illustrated in FIG. 13(A) illustrates a configuration of what is called a CMOS circuit in which the p-channel transistor 4200 and the n-channel transistor 4100 are connected in series and in which gates of them are connected to each other.

A circuit diagram illustrated in FIG. 13(B) illustrates a configuration in which a source and a drain of each of the transistor 4100 and the transistor 4200 are connected. With such a configuration, they can function as what is called an analog switch.

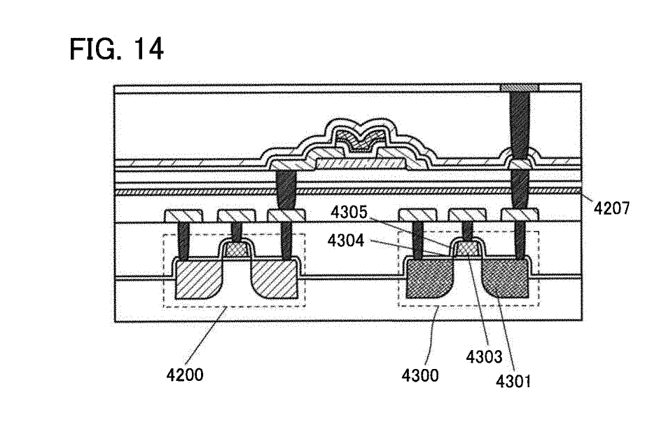

FIG. 14 is a cross-sectional view of a semiconductor device in which a CMOS circuit is formed using the transistor 4200 and a transistor 4300 which have a first semiconductor material in the channels.

The transistor 4300 includes impurity regions 4301 functioning as source and drain regions, a gate electrode 4303, a gate insulating film 4304, and a sidewall insulating film 4305. The transistor 4300 may also include an impurity region functioning as an LDD region under the sidewall insulating film 4305. For other components in FIG. 14, the description for FIG. 12(A) can be referred to.

The transistor 4200 and the transistor 4300 preferably have different polarities. For example, when the transistor 4200 is a p-channel transistor, the transistor 4300 is preferably an n-channel transistor.

The semiconductor device may have a structure including a photoelectric conversion element such as a photodiode.

The photoelectric conversion element can be formed using a single crystal semiconductor, a polycrystalline semiconductor, or an amorphous semiconductor, and the material may be selected in accordance with the usage. For example, as the material, single crystal silicon, polycrystalline silicon, microcrystalline silicon, amorphous silicon, polycrystalline selenium, amorphous selenium, CIS (compound of copper, indium, and selenium), CIGS (a compound of copper, indium, gallium, and selenium), or the like can be used.

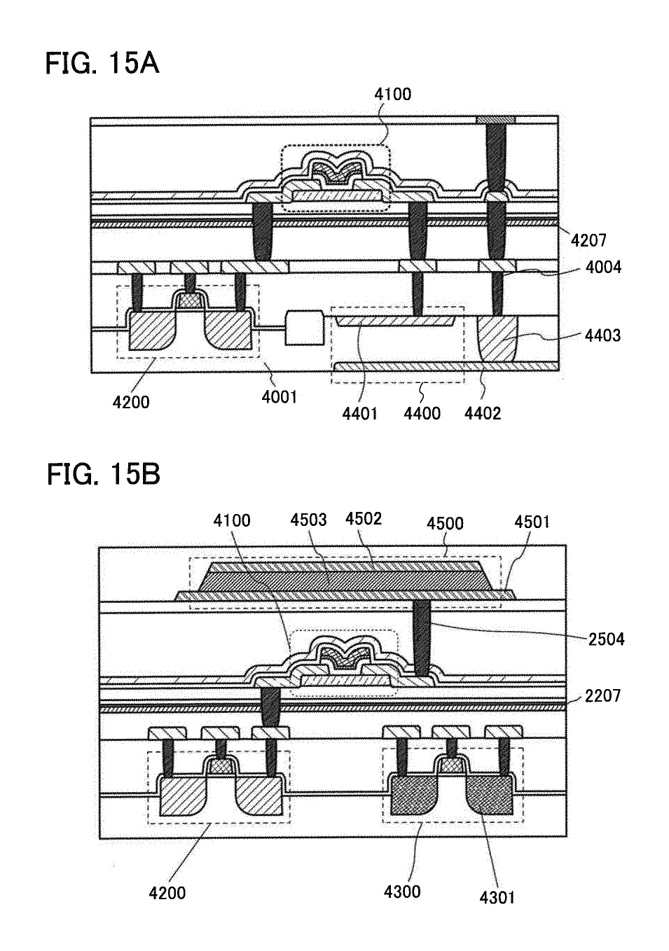

FIG. 15(A) is a cross-sectional view in the case where a substrate 4001 is provided with a photoelectric conversion element 4400. For example, the substrate 4001 can be a single crystal semiconductor. The photoelectric conversion element 4400 includes a conductive layer 4401 having a function of one of an anode and a cathode, a conductive layer 4402 having a function of the other of the anode and the cathode, and a conductive layer 4403 electrically connecting the conductive layer 4402 and a plug 4004. The conductive layer 4401 to the conductive layer 4403 can be manufactured by injecting or diffusing an impurities into the substrate 4001.

Although the photoelectric conversion element 4400 is provided so that current flows in the longitudinal direction with respect to the substrate 4001 in FIG. 15(A), the photoelectric conversion element 4400 may be provided so that current flows in the lateral direction with respect to the substrate 4001.

FIG. 15(B) is a cross-sectional view of a semiconductor device in which a photoelectric conversion element 4500 is provided in an upper layer of the transistor 4100. The photoelectric conversion element 4500 includes a conductive layer 4501 having a function of one of an anode and a cathode, a conductive layer 4502 having a function of the other of the anode and the cathode, and a semiconductor 4503. The photoelectric conversion element 4500 is electrically connected to the transistor 4100 via a plug 4504. In the structure, a pin-type photoelectric conversion element using, for example, i-type amorphous silicon can be used as the photoelectric conversion element 4500. Alternatively, a photoelectric conversion element using polycrystalline selenium or amorphous selenium may be used.

In FIG. 15(B), the photoelectric conversion element 4500 may be provided in the same level as the transistor 4100. Alternatively, the photoelectric conversion element 4500 may be provided at a level between the transistor 4200 and the transistor 4100.

The photoelectric conversion element 4400 and the photoelectric conversion element 4500 may be formed using a material capable of generating charge by absorbing a radiation. Examples of the material capable of generating charge by absorbing a radiation include selenium, lead iodide, mercury iodide, gallium arsenide, CdTe, and CdZn.

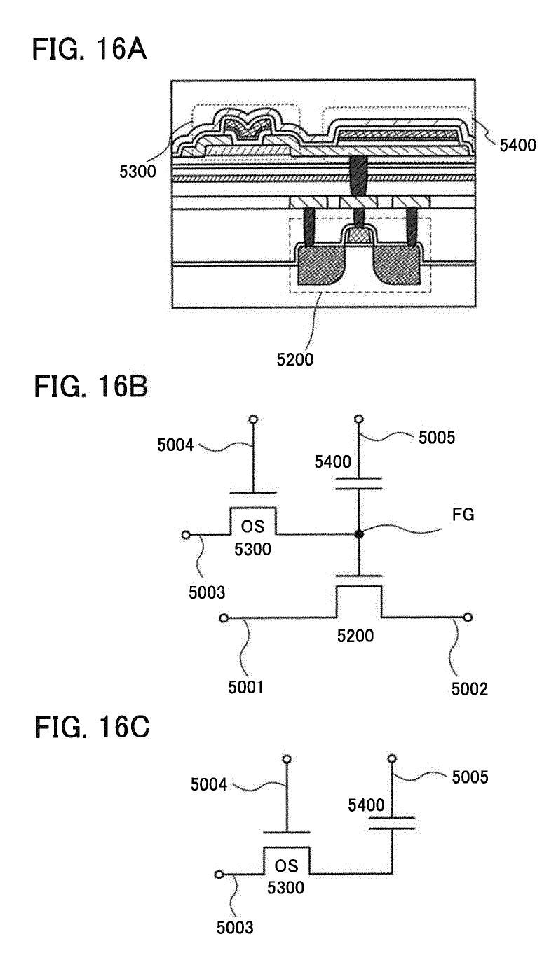

The semiconductor device can have a configuration including a memory circuit. FIG. 16 illustrates an example of a memory circuit which includes a transistor including an oxide semiconductor, which can hold stored data even when not powered and which has an unlimited number of write cycles. Note that FIG. 16(B) is a circuit diagram corresponding to FIG. 16(A).

The memory circuit illustrated in FIGS. 16(A) and (B) includes a transistor 5200 using a first semiconductor material, a transistor 5300 using a second semiconductor material, and a capacitor 5400. Note that the transistor shown in Embodiment 2 can be used as the transistor 5300.

The transistor 5300 is a transistor in which a channel is formed in a semiconductor including an oxide semiconductor. Since the off-state current of the transistor 5300 is small, stored data can be held for a long time owing to it. In other words, a semiconductor memory device in which refresh operation is unnecessary or the frequency of refresh operation is extremely low can be provided, leading to a sufficient reduction in power consumption.

In FIG. 16(B), a first wiring 5001 is electrically connected to a source electrode of the transistor 5200, and a second wiring 5002 is electrically connected to a drain electrode of the transistor 5200. A third wiring 5003 is electrically connected to one of a source electrode and a drain electrode of the transistor 5300, and a fourth wiring 5004 is electrically connected to a gate electrode of the transistor 5300. A gate electrode of the transistor 5200 and the other of the source electrode and the drain electrode of the transistor 5300 are electrically connected to one electrode of the capacitor 5400, and a fifth wiring 5005 is electrically connected to the other electrode of the capacitor 5400.

The memory circuit in FIG. 16(A) has a feature in which the potential of the gate electrode of the transistor 5200 can be retained, and thus enables writing, retaining, and reading of data as follows

Writing and holding of data will be described. First, the potential of the fourth wiring 5004 is set to a potential at which the transistor 5300 is turned on, so that the transistor 5300 is turned on. Accordingly, the potential of the third wiring 5003 is supplied to the gate electrode of the transistor 5200 and the capacitor 5400. That is, a predetermined charge is supplied to the gate of the transistor 5200 (writing). Here, one of two kinds of charges providing different potentials (hereinafter referred to as Low-level charge and High-level charge) is applied. After that, the potential of the fourth wiring 5004 is set to a potential at which the transistor 5300 is turned off, so that the transistor 5300 is turned off; whereby the charge supplied to the gate electrode of the transistor 5200 is held (retaining).

Since the off-state current of the transistor 5300 is extremely small, the charge of the gate of the transistor 5200 is held for a long time.

Next, reading of data is described. An appropriate potential (a reading potential) is supplied to the fifth wiring 5005 while a predetermined potential (a constant potential) is supplied to the first wiring 5001, whereby the potential of the second wiring 5002 varies depending on the amount of charge retained in the gate of the transistor 5200. This is because in the case of using an n-channel transistor as the transistor 5200, an apparent threshold voltage Vth_H at the time when High-level charge is given to the gate electrode of the transistor 5200 is lower than an apparent threshold voltage Vth_L at the time when Low-level charge is given to the gate electrode of the transistor 5200. Here, the apparent threshold voltage refers to the potential of the fifth wiring 5005, which is needed to bring the transistor 5200 into an “on state”. Thus, the potential of the fifth wiring 5005 is set to a potential V0 which is between Vth_H and Vth_L, whereby charge supplied to the gate of the transistor 5200 can be determined. For example, in the case where High-level charge is given in writing, when the potential of the fifth wiring 5005 is set to V0 (>Vth_H), the transistor 5200 is brought into an “on state”. In the case where Low-level charge is given in writing, even when the potential of the fifth wiring 5005 is set to V0 (<Vth_L), the transistor 5200 remains in an “off state”. Thus, the retained data can be read by determining the potential of the second wiring 5002.

In the case where memory cells are arrayed, it is necessary that only data of a designated memory cell(s) can be read. In the case where data is not read, the fifth wiring 5005 may be supplied with a potential at which the transistor 5200 is brought into an “off state” regardless of the state of the gate, that is, a potential lower than Vth_H. Alternatively, the fifth wiring 5005 may be supplied with a potential at which the transistor 5200 is brought into an “on state” regardless of the state of the gate, that is, a potential higher than Vth_L.

The semiconductor device illustrated in FIG. 16(C) is different from FIG. 16(A) in that the transistor 5200 is not provided. Also in this case, data writing and retaining operations can be performed in a manner similar to that described above.

Next, reading of data of the semiconductor device illustrated in FIG. 16(C) is described. When the transistor 5300 is brought into an on state, the third wiring 5003 which is in a floating state and the capacitor 5400 are brought into conduction, and the charge is redistributed between the third wiring 5003 and the capacitor 5400. As a result, the potential of the third wiring 5003 is changed. The amount of change in the potential of the third wiring 5003 varies depending on the potential of the first terminal of the capacitor 5400 (or the charge accumulated in the capacitor 5400).

For example, the potential of the capacitor 5400 after the charge redistribution is (CB×VB0+C×V)/(CB+C), where V is the potential of the first terminal of the capacitor 5400, C is the capacitance of the capacitor 5400, CB is the capacitance component of the third wiring 5003, and VB0 is the potential of the third wiring 3003 before the charge redistribution. Thus, it can be found that, assuming that the memory cell is in either of two states in which the potential of the first terminal of the capacitor 5400 is V1 and V0 (V1>V0), the potential of the third wiring 5003 in the case of retaining the potential V1 (=(CB×VB0+C×V1)/(CB+C)) is higher than the potential of the third wiring 5003 in the case of retaining the potential V0 (=(CB×VB0+C×V0)/(CB+C)).

Then, by comparing the potential of the third wiring 5003 with a predetermined potential, data can be read.

In this case, a transistor including the first semiconductor material may be used for a driver circuit for driving a memory cell, and a transistor including the second semiconductor material may be stacked over the driver circuit as the transistor 5300.

When including a transistor having a channel formation region formed using an oxide semiconductor and having extremely small off-state current, the memory circuit described in this embodiment can store data for an extremely long period. In other words, refresh operation becomes unnecessary or the frequency of the refresh operation can be extremely lowered, which leads to a sufficient reduction in power consumption. Furthermore, stored data can be held for a long period even during a period in which power is not supplied (note that the potential is preferably fixed).

In the memory circuit described in this embodiment, high voltage is not needed for writing data and there is no problem of deterioration of elements. For example, unlike a conventional nonvolatile memory, it is not necessary to inject and extract electrons into and from a floating gate, and thus a problem such as deterioration of a gate insulating film does not arise at all. That is, the memory circuit according to the disclosed invention does not have a limitation on the number of times data can be rewritten, which is a problem of a conventional nonvolatile memory, and the reliability thereof is drastically improved. Furthermore, since data is written by turning on or off the transistor, high-speed operation can be easily realized.

The memory device described in this embodiment can also be used in an LSI such as a central processing unit (CPU), a digital signal processor (DSP), a custom LSI, or a programmable logic device (PLD), for example.

The structure described in this embodiment can be used in appropriate combination with the structure described in any of the other embodiments.

### Embodiment 5

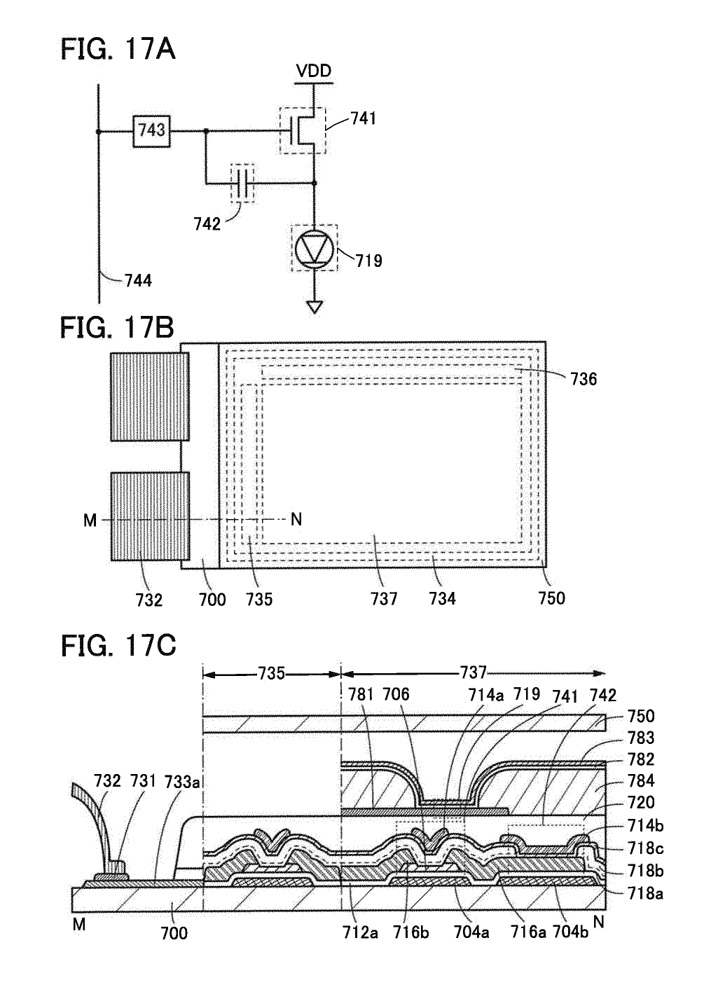

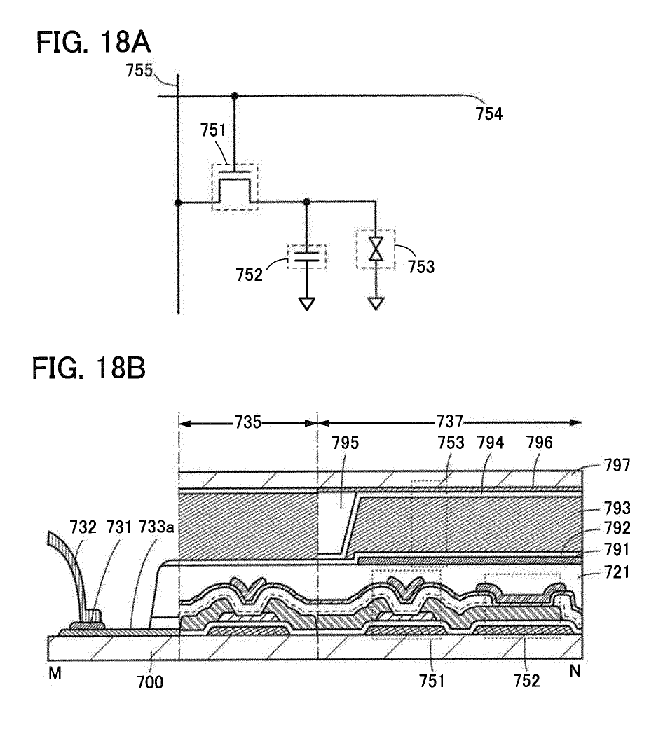

In this embodiment, a display device that can be used for a display portion of the electronic device of one embodiment of the present invention is described with reference to FIG. 17 and FIG. 18.

Examples of a display element used in the display device include a liquid crystal element (also referred to as a liquid crystal display element) and a light-emitting element (also referred to as a light-emitting display element). The light-emitting element includes, in its category, an element whose luminance is controlled by a current or voltage, and specifically includes, in its category, inorganic EL (Electroluminescence), organic EL, and the like. A display device including an EL element (EL display device) and a display device including a liquid crystal element (liquid crystal display device) are described below as examples of the display device.

Note that the display device described below includes a panel in which a display element is sealed and a module in which an IC such as a controller is mounted on the panel.

The display device described below refers to an image display device or a light source (including a lighting device). In addition, it includes any of a module provided with a connector such as an FPC or TCP; a module in which a printed wiring board is provided at the end of TCP; and a module in which an integrated circuit (IC) is mounted directly on a display element by a COG method.

FIG. 17 illustrates an example of an EL display device according to one embodiment of the present invention. FIG. 17(A) is a circuit diagram of a pixel of the EL display device. FIG. 17(B) is a top view illustrating the whole of the EL display device. FIG. 17(C) illustrates an M-N cross section corresponding to part of dashed-dotted line M-N in FIG. 17(B).

FIG. 17(A) illustrates an example of a circuit diagram of a pixel used in the EL display device.

The EL display device illustrated in FIG. 17(A) includes a switching element 743, a transistor 741, a capacitor 742, and a light-emitting element 719.

Note that FIG. 17(A) and the like each illustrate an example of a circuit configuration; therefore, a transistor can be provided additionally. In contrast, for each node in FIG. 17(A), it is possible not to provide an additional transistor, switch, passive element, or the like.

A gate of the transistor 741 is electrically connected to one terminal of the switching element 743 and one electrode of the capacitor 742. A source of the transistor 741 is electrically connected to the other electrode of the capacitor 742 and electrically connected to one electrode of the light-emitting element 719. A power supply potential VDD is supplied to the source of the transistor 741. The other terminal of the switching element 743 is electrically connected to a signal line 744. A constant potential is supplied to the other electrode of the light-emitting element 719. The constant potential is a ground potential GND or a potential lower than the ground potential GND.

It is preferable to use a transistor as the switching element 743. When the transistor is used, the area of a pixel can be reduced, so that the EL display device can have high resolution. As the switching element 743, a transistor formed through the same step as the transistor 741 can be used, so that EL display devices can be manufactured with high productivity. Note that as the transistor 741 and/or the switching element 743, the above-described transistor can be used, for example.

FIG. 17(B) is a top view of the EL display device. The EL display device includes a substrate 700, a substrate 750, a sealant 734, a driver circuit 735, a driver circuit 736, a pixel 737, and an FPC 732. The sealant 734 is provided between the substrate 700 and the substrate 750 so as to surround the pixel 737, the driver circuit 735, and the driver circuit 736. Note that the driver circuit 735 and/or the driver circuit 736 may be provided outside the sealant 734.

FIG. 17(C) is a cross-sectional view of the EL display device taken along part of the dashed-dotted line M-N in FIG. 17(B).

FIG. 17(C) illustrates a structure of the transistor 741 including a conductor 704a over the substrate 700; an insulator 712a over the conductor 704a; an insulator 712; a semiconductor 706 that is over the insulator 712 and overlaps the conductor 704a; a conductor 716a and a conductor 716b in contact with the semiconductor 706; an insulator 718a over the semiconductor 706, the conductor 716a, and the conductor 716b; an insulator 718b over the insulator 718a; an insulator 718c over the insulator 718b; and a conductor 714a that is over the insulator 718c and overlaps a semiconductor 706b. Note that this structure of the transistor 741 is an example; a structure different from the structure illustrated in FIG. 17(C) may be employed.

Therefore, in the transistor 741 illustrated in FIG. 17(C), the conductor 704a has a function of a gate electrode, the insulator 712 has a function of a gate insulator, the conductor 716a has a function of a source electrode, the conductor 716b has a function of a drain electrode, the insulator 718a, the insulator 718b, and the insulator 718c have a function of a gate insulator, and the conductor 714a has a function of a gate electrode. Note that in some cases, the electrical characteristics of the semiconductor 706 change if light enters the semiconductor 706. Thus, it is preferable that one or more of the conductor 704a, the conductor 716a, the conductor 716b, and the conductor 714a have a light-blocking property.

Note that the interface between the insulator 718a and the insulator 718b is indicated by a broken line; this means that the boundary between them is not clear in some cases. For example, in the case where insulators of the same kind are used as the insulator 718a and the insulator 718b, they are not distinguished from each other in some cases depending on an observation method. In addition, a single-layer insulator may be provided in a region where the insulator 718a and the insulator 718b are provided.

FIG. 17(C) illustrates a structure of the capacitor 742 which a conductor 704b over the substrate; the insulator 712 over the conductor 704b; the conductor 716a that is over the insulator 712 and overlaps the conductor 704b; the insulator 718a over the conductor 716a; the insulator 718b over the insulator 718a; the insulator 718c over the insulator 718b; and a conductor 714b that is over the insulator 718c and overlaps the conductor 716a, and in which parts of the insulator 718a and the insulator 718b are removed in a region where the conductor 716a and the conductor 714b overlap each other.

In the capacitor 742, the conductor 704b and the conductor 714b serves as one electrode, and the conductor 716a serves as the other electrode.

Thus, the capacitor 742 can be formed using a film common to the transistor 741. The conductor 704a and the conductor 704b are preferably conductors of the same kind. In that case, the conductor 704a and the conductor 704b are preferably formed through the same step. The conductor 714a and the conductor 714b are preferably conductors of the same kind. In this case, the conductor 714a and the conductor 714b can be formed through the same step.

The capacitor 742 illustrated in FIG. 17(C) is a capacitor which has a large capacitance per occupation area. Therefore, the EL display device illustrated in FIG. 17(C) has high display quality. Note that although the capacitor 742 illustrated in FIG. 17(C) has the structure in which parts of the insulator 718a and the insulator 718b are removed to reduce the thickness of the region where the conductor 716a and the conductor 714b overlap each other, the capacitor according to one embodiment of the present invention is not limited thereto. For example, a structure in which a part of the insulator 718c is removed to reduce the thickness of the region where the conductor 716a and the conductor 714b overlap each other may be used.

An insulator 720 is provided over the transistor 741 and the capacitor 742. Here, the insulator 720 may have an opening reaching the conductor 716a that serves as the source electrode of the transistor 741. A conductor 781 is provided over the insulator 720. The conductor 781 may be electrically connected to the transistor 741 through the opening in the insulator 720.

A partition wall 784 having an opening reaching the conductor 781 is provided over the conductor 781. A light-emitting layer 782 in contact with the conductor 781 through the opening formed in the partition wall 784 is provided over the partition wall 784. A conductor 783 is provided over the light-emitting layer 782. A region where the conductor 781, the light-emitting layer 782, and the conductor 783 overlap one another serves as the light-emitting element 719.

So far, examples of the EL display device are described. Next, an example of a liquid crystal display device will be described.

FIG. 18(A) is a circuit diagram illustrating a configuration example of a pixel of a liquid crystal display device. The pixel illustrated in FIG. 18 includes a transistor 751, a capacitor 752, and an element (liquid crystal element) 753 in which a space between a pair of electrodes is filled with a liquid crystal.

One of a source and a drain of the transistor 751 is electrically connected to a signal line 755, and a gate thereof is electrically connected to a scan line 754.

One electrode of the capacitor 752 is electrically connected to the other of the source and the drain of the transistor 751, and the other electrode is electrically connected to a wiring for supplying a common potential.

One electrode of the liquid crystal element 753 is electrically connected to the other of the source and the drain of the transistor 751, and the other electrode is electrically connected to a wiring to which a common potential is supplied. The common potential supplied to the wiring electrically connected to the other electrode of the capacitor 752 may be different from that supplied to the other electrode of the liquid crystal element 753.

Note that the description of the liquid crystal display device is made on the assumption that the top plan view of the liquid crystal display device is similar to that of the EL display device. FIG. 18(B) is a cross-sectional view of the liquid crystal display device taken along dashed-dotted line M-N in FIG. 17(B). In FIG. 18(B), the FPC 732 is connected to a wiring 733a via a terminal 731. Note that the wiring 733a may be formed using the same kind of conductor as the conductor of the transistor 751 or using the same kind of semiconductor as the semiconductor of the transistor 751.

For the transistor 751, the description of the transistor 741 is referred to. For the capacitor 752, the description of the capacitor 742 is referred to. Although a structure which is similar to the capacitor 742 in FIG. 17(C) is illustrated as the capacitor 752 illustrated in FIG. 18(B), it is not limited thereto.

Note that in the case where an oxide semiconductor is used as the semiconductor of the transistor 751, it can be a transistor in which the off-state current is extremely small. Therefore, an electric charge held in the capacitor 752 is unlikely to leak, so that the voltage applied to the liquid crystal element 753 can be maintained for a long time. Accordingly, the transistor 751 can be kept off during a period in which moving images with few motions or a still image are/is displayed, whereby power for the operation of the transistor 751 can be saved in that period; accordingly a liquid crystal display device with low power consumption can be provided. Furthermore, the area occupied by the capacitor 752 can be reduced; thus, a liquid crystal display device with a high aperture ratio or a high-resolution liquid crystal display device can be provided.

An insulator 721 is provided over the transistor 751 and the capacitor 752. Here, the insulator 721 has an opening reaching the transistor 751. A conductor 791 is provided over the insulator 721. The conductor 791 is electrically connected to the transistor 751 through the opening in the insulator 721.

An insulator 792 serving as an alignment film is provided over the conductor 791. A liquid crystal layer 793 is provided over the insulator 792. An insulator 794 serving as an alignment film is provided over the liquid crystal layer 793. A spacer 795 is provided over the insulator 794. A conductor 796 is provided over the spacer 795 and the insulator 794. A substrate 797 is provided over the conductor 796.

Owing to the above-described structure, a display device including a capacitor occupying a small area, a display device with high display quality, or a high-resolution display device can be provided. A high-resolution display device can be provided.

For example, in this specification and the like, a display element, a display device which is a device including a display element, a light-emitting element, and a light-emitting device which is a device including a light-emitting element can employ various modes or can include various elements. For example, the display element, the display device, the light-emitting element, or the light-emitting device includes at least one of a light-emitting diode (LED) for white, red, green, blue, or the like, a transistor (a transistor that emits light depending on current), an electron emitter, a liquid crystal element, electronic ink, an electrophoretic element, a grating light valve (GLV), a plasma display panel (PDP), a display element using MEMS (micro electro mechanical systems), a digital micromirror device (DMD), DMS (a digital micro shutter), an IMOD (interferometric modulator display) element, a MEMS shutter display element, an optical-interference-type MEMS display element, an electrowetting element, a piezoelectric ceramic display, and a display element including a carbon nanotube. In addition to the above, a display medium whose contrast, luminance, reflectivity, transmittance, or the like changes by electrical or magnetic action may be included.

Note that examples of display devices having EL elements include an EL display. Examples of a display device including an electron emitter include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples of a display device including electronic ink, or an electrophoretic element include electronic paper. In the case of a transflective liquid crystal display or a reflective liquid crystal display, some of or all of pixel electrodes function as reflective electrodes. For example, some or all of pixel electrodes are formed to contain aluminum, silver, or the like. In such a case, a memory circuit such as an SRAM can be provided under the reflective electrodes. Thus, the power consumption can be further reduced.

Note that in the case of using an LED, graphene or graphite may be provided under an electrode or a nitride semiconductor of the LED. Graphene or graphite may be a multilayer film in which a plurality of layers are stacked. As described above, provision of graphene or graphite enables easy formation of a nitride semiconductor thereover, such as an n-type GaN semiconductor including crystals. Furthermore, a p-type GaN semiconductor including crystals or the like can be provided thereover, and thus the LED can be formed. Note that an AlN layer may be provided between the n-type GaN semiconductor including crystals and graphene or graphite. The GaN semiconductors included in the LED may be formed by MOCVD. Note that when the graphene is provided, the GaN semiconductor included in the LED can also be formed by a sputtering method.

The structure described in this embodiment can be used in appropriate combination with the structure described in any of the other embodiments.

### Embodiment 6

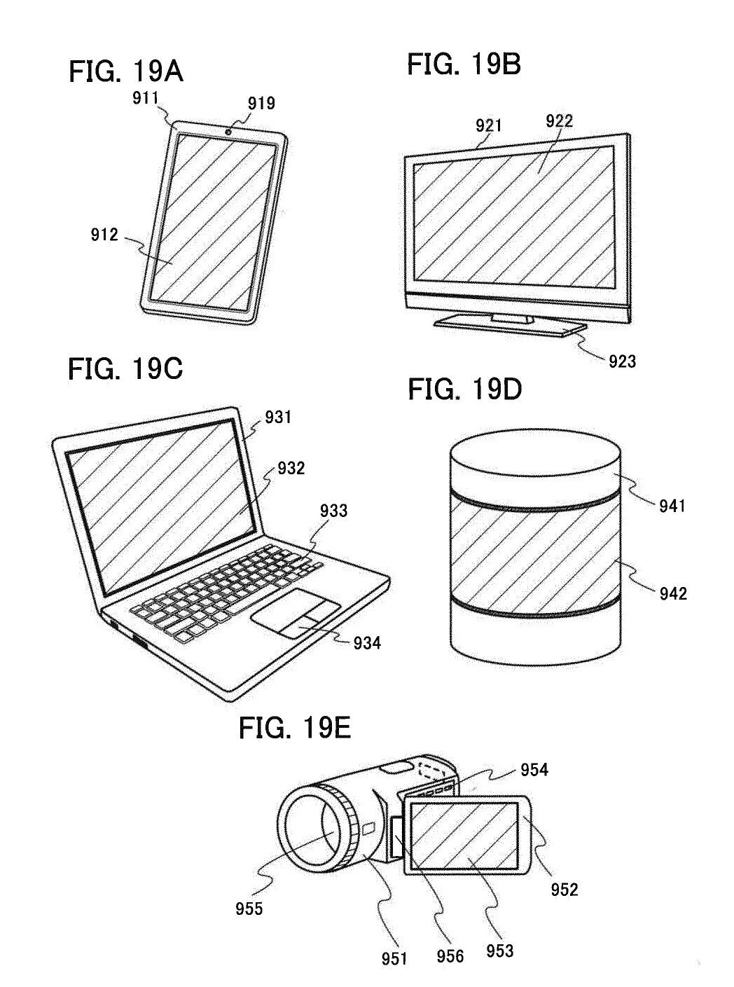

The electronic device according to one embodiment of the present invention can be used as a display device, a personal computer, or an image reproducing device provided with a recording medium (typically a device which reproduces the content of a recording medium such as a DVD (Digital Versatile Disc) and has a display for displaying the reproduced image). Other than the above, the electronic device according to one embodiment of the present invention can be used as a mobile phone, a game machine including a portable one, a portable information terminal, an e-book reader, a camera such as a video camera or a digital still camera, a goggle-type display (a head mounted display), a navigation system, an audio reproducing device (e.g., a car audio system and a digital audio player), a copier, a facsimile, a printer, a multifunction printer, an automated teller machine (ATM), a vending machine, or the like. FIG. 19 illustrates specific examples of these electronic devices.

FIG. 19(A) illustrates a portable data terminal which includes a housing 911, a display portion 912, a camera 919, and the like. The touch panel function of the display portion 912 enables input and output of information. The electronic device of one embodiment of the present invention can be used for the portable data terminal.

FIG. 19(B) illustrates a television device in which a display portion 922 and a speaker are incorporated in a housing 921. The display portion 922 can display images. The housing 921 is supported by a stand 923. The electronic device of one embodiment of the present invention can be used for the television device.

FIG. 19(C) illustrates a notebook personal computer which includes a housing 931, a display portion 932, a keyboard 933, a pointing device 934, and the like. The electronic device of one embodiment of the present invention can be used for the notebook personal computer.

FIG. 19(D) illustrates a digital signage including a display portion 942 provided on a utility pole 941. The display portion 942 has flexibility. The electronic device of one embodiment of the present invention can be used for the digital signage.

FIG. 19(E) illustrates a video camera which includes a first housing 951, a second housing 952, a display portion 953, switches 954, a lens 955, a joint 956, and the like. The switches 954 and the lens 955 are provided for the first housing 951, and the display portion 953 is provided for the second housing 952. In addition, the first housing 951 includes a battery, and sound can be recorded with a microphone. The electronic device of one embodiment of the present invention can be used for the video camera.

Note that this embodiment can be combined with any of the other embodiments in this specification as appropriate.

### REFERENCE NUMERALS

10 signal output device
15 signal input/output device
20 display device
21 display device
31 wired transmission path
32 path
33 path
100 transistor
110 substrate
130 oxide semiconductor
130a oxide semiconductor
130b oxide semiconductor
130c oxide semiconductor
140 conductor
150 conductor
160 insulator
170 conductor
171 conductor
172 conductor
175 conductor
180 insulator
200 transistor
210 substrate
230 semiconductor
240 conductor
250 conductor
260 insulator
275 conductor
300 transistor
310 substrate
330 semiconductor
330a semiconductor
330b semiconductor
330c semiconductor
340 conductor
350 conductor
360 insulator
370 conductor
380 insulator
390 insulator
700 substrate
704a conductor
704b conductor
706 semiconductor
706b semiconductor
712 insulator
712a insulator
714a conductor
714b conductor
716a conductor
716b conductor
718a insulator
718b insulator
718c insulator
719 light-emitting element
720 insulator
721 insulator
731 terminal
732 FPC
733a wiring
734 sealant
735 driver circuit
736 driver circuit
737 pixel
741 transistor
742 capacitor
743 switching element
744 signal line
750 substrate
751 transistor
752 capacitor
753 liquid crystal element
754 scan line
755 signal line
781 conductor
782 light-emitting layer
783 conductor
784 partition wall
791 conductor
792 insulator
793 liquid crystal layer
794 insulator
795 spacer
796 conductor
797 substrate
911 housing
912 display portion
919 camera
921 housing
922 display portion
923 stand
931 housing
932 display portion
933 keyboard
934 pointing device
941 utility pole
942 display portion
951 housing
952 housing
953 display portion
954 switch
955 lens
956 joint
1000 device
1100 circuit
1200 circuit
1300 circuit
1400 circuit
1500 antenna
2000 display portion
2100 circuit
2150 memory circuit
2300 circuit
2400 circuit
2500 antenna
3000 battery
3100 input/output terminal
3200 input/output terminal
3300 operation button
3400 camera
3500 cable
4001 substrate
4004 plug
4100 transistor
4200 transistor
4201 insulating film
4202 wiring
4203 plug
4204 interlayer insulating film
4207 insulating film
4211 semiconductor substrate
4212 insulating film
4213 gate electrode
4214 gate insulating film
4215 drain region
4300 transistor
4301 impurity region
4303 gate electrode
4304 gate insulating film
4305 sidewall insulating film
4400 photoelectric conversion element
4401 conductive layer
4402 conductive layer
4403 conductive layer
4500 photoelectric conversion element
4501 conductive layer
4502 conductive layer
4503 semiconductor
4504 plug
5001 wiring
5002 wiring
5003 wiring
5004 wiring
5005 wiring
5200 transistor
5300 transistor
5400 capacitor

1. An electronic device comprising a signal output device and a display device,
wherein the signal output device has a function of dividing an image signal into a plurality of signals,
wherein the display device has a function of combining the plurality of signals,
wherein the plurality of signals comprises a first signal and a second signal,
wherein the signal output device has a function of transmitting the first signal to the display device via a wired transmission path, and
wherein the signal output device has a function of transmitting the second signal to the display device via a wireless transmission path.

2. An electronic device comprising a signal output device and a display device,
wherein the signal output device has a function of transmitting a first signal to the display device via a wired transmission path,
wherein the signal output device has a function of transmitting a second signal to the display device via a wireless transmission path,
wherein the signal output device comprises a first circuit, a second circuit, a third circuit, a fourth circuit, and a first antenna,
wherein the first circuit has a function of selecting a transmission path of an image signal,
wherein the second circuit has a function of dividing an image signal transmitted from the first circuit into a plurality of signals,
wherein the plurality of signals comprises the first signal and the second signal,
wherein the third circuit has a function of converting the first signal transmitted from the second circuit into a modulation signal,
wherein the fourth circuit has a function of sending the modulation signal transmitted from the third circuit with use of the first antenna,
wherein the display device comprises a fifth circuit, a sixth circuit, a seventh circuit, a second antenna, and a display portion,
wherein the fifth circuit has a function of receiving the modulation signal sent from the fourth circuit with use of the second antenna,
wherein the sixth circuit has a function of demodulating the modulation signal transmitted from the fifth circuit and converting it to the first signal, and
wherein the seventh circuit has a function of composing an image displayed on the display portion from the second signal transmitted from the second circuit and the first signal transmitted from the sixth circuit.

3. The electronic device according to claim 2, wherein the fourth circuit has a function of sending the modulation signal with use of electric waves with a plurality of frequency bands.

4. The electronic device according to claim 2, wherein the fifth circuit has a function of receiving the modulation signal sent with use of electric waves with a plurality of frequency bands.

5. The electronic device according to claim 2, wherein the number of wired transmission paths is two or more.

6. The electronic device according to claim 1,
wherein the signal output device and the display device comprise a transistor in which an oxide semiconductor is included in an active layer, and
wherein the oxide semiconductor comprises In, Zn, and M (M is Al, Ti, Ga, Sn, Y, Zr, La, Ce, Nd, or Hf).

7. An electronic device comprising:
the signal output device and the display device according to claim 1; and
at least one of a camera, a battery, a switch, a microphone, and a speaker.

8. The electronic device according to claim 2,
wherein the signal output device and the display device comprise a transistor in which an oxide semiconductor is included in an active layer, and
wherein the oxide semiconductor comprises In, Zn, and M (M is Al, Ti, Ga, Sn, Y, Zr, La, Ce, Nd, or Hf).

9. An electronic device comprising:
the signal output device and the display device according to claim 2; and
at least one of a camera, a battery, a switch, a microphone, and a speaker.
